(19) United States
(12) Patent Application Publication
(10) Pub. No.: US 2018/0188575 A1
(43) Pub. Date: Jul. 5, 2018

(54) ACTIVE MATRIX SUBSTRATE, DISPLAY DEVICE, AND MANUFACTURING METHOD

(71) Applicant: SHARP KABUSHIKI KAISHA, Sakai City, Osaka (JP)

(72) Inventors: TOMOHIRO KOSAKA, Sakai City (JP); TAKESHI HARA, Sakai City (JP); TOHRU OKABE, Sakai City (JP); IZUMI ISHIDA, Sakai City (JP); SHOGO MURASHIGE, Sakai City (JP); KENICHI KITOH, Sakai City (JP); HIROHIKO NISHIKI, Sakai City (JP)

(21) Appl. No.: 15/741,343

(22) PCT Filed: Jul. 7, 2016
(86) PCT No.: PCT/JP2016/070175

§ 371 Date: Jan. 2, 2018

(30) Foreign Application Priority Data
Jul. 9, 2015 (JP) 2015-137643
Jul. 17, 2015 (JP) 2015-143450

(51) Int. Cl. G02F 1/1368; H01L 27/12; G02F 1/1362

(52) U.S. Cl. CPC G02F 1/1368; H01L 27/1225; H01L 27/3262; G02F 1/136286; G02F 1/136227; H01L 27/124

(57) ABSTRACT

An active matrix substrate includes an insulating substrate (100); a surface coating film (110) that covers at least a part of a surface of the insulating substrate; an insulating light-transmitting film (204) provided on the insulating substrate including the surface coating film; gate lines; a gate insulating film; thin film transistors; data lines; and lead-out lines (115). In a peripheral portion of the insulating substrate, an area where the insulating light-transmitting film is not provided is formed. The lead-out line is provided so as to intersect with an outer circumference end of the insulating light-transmitting film, when viewed in a direction vertical to the insulating substrate. In the area where the insulating light-transmitting film is not provided, the surface coating film is also provided on a part in contact with the outer circumference end of the insulating light-transmitting film.

### TECHNICAL FIELD

The present invention relates to an active matrix substrate on which thin film transistors are arranged, and a display device in which the same is used.

### BACKGROUND ART

Among display devices, some include thin film transistors arranged in matrix on a substrate. In recent years, oxide semiconductors having characteristics such as high mobility and low leakage current are used as thin film transistors. The range of the use of an active matrix substrate that includes thin film transistors formed with an oxide semiconductor is extending. Such an active matrix substrate is used in, for example, a liquid crystal display that is required to be high-definition, a current-driven organic EL display in which heavy loads are applied on thin film transistors, a microelectromechanical system (MEMS) display that is required to control actions of shutters at a high speed, and the like.

For example, Patent Document 1 indicated below discloses a transmission type MEMS display. In this MEMS display, on a first substrate that includes thin film transistors, a plurality of shutters of MEMS are arrayed in matrix so as to correspond to the pixels, respectively. On a light-shielding film laminated on a first-substrate-side surface of a second substrate, a plurality of openings are provided that are arrayed in matrix so as to correspond to the pixels, respectively. When the shutter portions move, the openings are opened or closed, which cause light from a backlight unit to be transmitted toward the display surface or to be blocked.

### PRIOR ART DOCUMENT

### Patent Document

Patent Document 1: JP-A-2013-50720

### SUMMARY OF THE INVENTION

### Problem to be Solved by the Invention

As a configuration of an active matrix substrate, the following configuration is being considered by the inventors of the present application: on an insulating substrate, an insulating light-transmitting film is formed, and thin film transistors are laminated thereon so as to correspond to pixels, respectively. In the case of this configuration, at a step of patterning the light-transmitting film, a plurality of needle-like protrusions (protrusions in a needle-point holder form) can be formed on surfaces of the light-transmitting film and the substrate, in the vicinity of an end of the etched light-transmitting film. This was found by the inventors of the present application. Such protrusions adversely affect members laminated on the light-transmitting film. For example, when a line is laminated on protrusions, there could be a risk that the line has a high resistance, that the line becomes disconnected, or the like.

In order to stabilize the properties of thin film transistors in which an oxide semiconductor is used, a high temperature annealing treatment may be applied at a temperature of 400° C. or higher (hereinafter an annealing treatment at 400° C. or higher is referred to as “high temperature annealing treatment”), for about one hour, after an oxide semiconductor is deposited so that a layer of the same is formed. In a case where amorphous silicon is used for thin film transistors, the highest temperature in the active matrix substrate forming process is more or less about 300° C. to 330° C. (the temperature when silicon nitride or amorphous silicon is deposited); but in the active matrix substrate forming process in which an oxide semiconductor is used, the above-mentioned temperature of the high temperature annealing treatment is the highest temperature. Further, since the high temperature annealing treatment is carried out for a long duration such as one hour, problems tend to occur that did not arise in the conventional active matrix substrate forming process. For example, if high temperature annealing is performed in a state in which the needle-like protrusions as described above are formed, peeling-off of the light-shielding film, cracks, and the like tend to occur. The above-described problems, therefore, appear noticeably, in a case where thin film transistors formed with an oxide semiconductor are used.

Such a problem could occur to a display device, such as a liquid crystal display or an organic EL display, which has a configuration in which thin film transistors are arranged on an insulating layer formed on a substrate.

The present application discloses a display device in which the formation of protrusions on an insulating layer provided between a substrate and thin film transistors, or on a surface of the substrate, can be suppressed.

### Means to Solve the Problem

An active matrix substrate according to one embodiment of the present invention includes: an insulating substrate; a surface coating film that covers at least a part of a surface of the insulating substrate; an insulating light-transmitting film provided on the insulating substrate including the surface coating film; a gate line provided on the insulating light-transmitting film; a gate insulating film provided on the gate line; a data line provided on the gate insulating film so as to intersect with the gate line; a thin film transistor provided at a position corresponding to each point of intersection between the gate line and the data line; and a lead-out line that is electrically connected with the gate line or the data line. The surface coating film is provided between the insulating substrate and the insulating light-transmitting film. In a peripheral portion of the insulating substrate, an area where the insulating light-transmitting film is not provided is formed. The lead-out line is provided so as to intersect with an outer circumference end of the insulating light-transmitting film, when viewed in a direction vertical to the insulating substrate. In the area where the insulating light-transmitting film is not provided, the surface coating film is also provided on a part in contact with the outer circumference end of the insulating light-transmitting film.

### Effect of the Invention

With the configuration of the display device according to the disclosure of the present application, it is possible to suppress the formation of protrusions on a surface of an insulating layer provided between a substrate and thin film transistors, or on a surface of the substrate.

### BRIEF DESCRIPTION OF DRAWINGS

FIG. 1 is a perspective view illustrating a schematic configuration of a display device.

FIG. 2 is an equivalent circuit diagram of the display device.

FIG. 3 is a perspective view of a shutter portion.

FIG. 4 is a plan view for explaining an operation of the shutter portion.

FIG. 5 is a cross-sectional view taken along line V-V in FIG. 4.

FIG. 6 is a plan view for explaining an operation of the shutter portion.

FIG. 7 is a cross-sectional view taken along line VII-VII in FIG. 6.

FIG. 8 is a cross-sectional view of a first substrate.

FIG. 9 is a plan view illustrating a light-shielding film.

FIG. 10 is a cross-sectional view illustrating a peripheral portion of the light-transmitting film.

FIG. 11A illustrates an example of an area where a light-transmitting film is formed, when viewed in a direction vertical to the substrate.

FIG. 11B is a plan view of the vicinity of an end of the light-shielding layer illustrated in FIG. 10, when viewed in the direction vertical to the substrate.

FIG. 12 is an explanatory view illustrating a method for manufacturing the first substrate.

FIG. 13 is an explanatory view illustrating the method for manufacturing the first substrate.

FIG. 14 is an explanatory view illustrating the method for manufacturing the first substrate.

FIG. 15 is an explanatory view illustrating the method for manufacturing the first substrate.

FIG. 16 is an explanatory view illustrating the method for manufacturing the first substrate.

FIG. 17 is an explanatory view illustrating the method for manufacturing the first substrate.

FIG. 18 is an explanatory view illustrating the method for manufacturing the first substrate.

FIG. 19 is an explanatory view illustrating the method for manufacturing the first substrate.

FIG. 20 schematically illustrates a manufacturing flow of the manufacturing method illustrated in FIGS. 12 to 19.

FIG. 21 is a cross-sectional view illustrating a schematic configuration of a display device in Embodiment 2.

FIG. 22 is a cross-sectional view illustrating an exemplary configuration in the vicinity of an end of the light-transmitting film illustrated in FIG. 21.

FIG. 23 illustrates an exemplary configuration of a display device illustrated in FIGS. 21 and 22.

FIG. 24 is a cross-sectional view illustrating an exemplary configuration of a display device in Embodiment 3.

FIG. 25 is a cross-sectional view illustrating an exemplary configuration of the vicinity of an end of the light-transmitting film illustrated in FIG. 24.

### MODE FOR CARRYING OUT THE INVENTION

An active matrix substrate according to one embodiment of the present invention includes: an insulating substrate; a surface coating film that covers at least a part of a surface of the insulating substrate; an insulating light-transmitting film provided on the insulating substrate including the surface coating film; a gate line provided on the insulating light-transmitting film; a gate insulating film provided on the gate line; a data line provided on the gate insulating film so as to intersect with the gate line; a thin film transistor provided at a position corresponding to each point of intersection between the gate line and the data line; and a lead-out line that is electrically connected with the gate line or the data line. The surface coating film is provided between the insulating substrate and the insulating light-transmitting film. In a peripheral portion of the insulating substrate, an area where the insulating light-transmitting film is not provided is formed. The lead-out line is provided so as to intersect with an outer circumference end of the insulating light-transmitting film, when viewed in a direction vertical to the insulating substrate. In the area where the insulating light-transmitting film is not provided, the surface coating film is also provided on a part in contact with the outer circumference end of the insulating light-transmitting film.

According to the above-described configuration, on the insulating substrate, in an area where the insulating light-transmitting film is not provided, the surface coating film is provided on a part in contact with the end of the insulating light-transmitting film. In other words, in an area where the insulating light-transmitting film is removed on the insulating substrate, the surface coating film is left to remain in the part in contact with the end of the insulating light-transmitting film. If no surface coating film is provided in a part in contact with the end of insulating light-transmitting film and the substrate surface is reduced by over-etching or the like in the step of removing the insulating light-transmitting film, protrusions tend to be formed on a surface of the substrate or the insulating light-transmitting film. To cope with this, as in the above-described configuration, the surface coating film is left to remain in an area in contact with the end of the insulating light-transmitting film, whereby the formation of such protrusions is suppressed. Lead-out lines are provided so as to be extended over the end of the insulating light-transmitting film in the part that the surface coating film is in contact with. This makes it less likely that, due to protrusions, disconnection would occur to the lead-out lines that pass over the end of the insulating light-transmitting film and are led toward the outside, or these lead-out lines would have a high resistance. As a result, it is possible to suppress the occurrence of defects in operations of the elements laminated on the insulating light-transmitting film.

The insulating light-transmitting film, in a part thereof, may include a light-shielding area. The light-shielding area is provided at least in an area that is superposed on the gate line and the data line, when viewed in the direction vertical to the insulating substrate. With this, a light-shielding layer that is capable of selectively blocking light passing through the insulating substrate can be formed between the insulating substrate and the thin film transistor.

The light-shielding area may be formed with a light-shielding film provided between the surface coating film and the insulating light-transmitting film. In this case, the light-shielding film has a plurality of openings. With this configuration, steps formed by the light-shielding film can be reduced by the insulating light-transmitting film. This makes it easier to flatten the surface of the film covering the light-shielding film. Further, with the insulating light-transmitting film, a distance between members laminated on the insulating light-transmitting film and the light-shielding film can be easily ensured.

The end surface of the insulating light-transmitting film may form a surface inclined in such a manner that a height thereof from a surface of the substrate decreases as proximity thereof to a region where the pixels are arranged decreases. This makes it possible to make steps at the end of the light-transmitting film smaller. As a result, influences caused by steps onto the members laminated over the light-transmitting film can be reduced.

An angle formed between an end surface of the insulating light-transmitting film and the insulating substrate can be set to, for example, 3° to 10°. This makes it possible to effectively suppress the disconnection of a line or the like that gets onto the insulating light-shielding film from the surface of the substrate.

The surface coating film is made of a material that is etched to a lower degree in the etching performed during patterning of the insulating light-transmitting film, as compared with the material of the insulating light-transmitting film. This allows the surface coating film to be more surely left to remain during the patterning of the insulating light-transmitting film. The surface coating film can be made of, for example, SiO₂.

The insulating light-transmitting film can be formed with an SOG film. This makes it easier to flatten the surface of the insulating light-transmitting film. Though some materials for the SOG film tend to form protrusions when being formed on the substrate, the surface coating film thus provided makes it possible to effectively suppress the formation of protrusions even in a case where the insulating light-transmitting film is formed with an SOG film.

The thin film transistor contains an oxide semiconductor. In order to stabilize the properties of thin film transistors in which an oxide semiconductor is used, in some cases, high temperature annealing may be applied at a temperature of 400° C. or higher (hereinafter an annealing treatment at 400° C. or higher is referred to as “high temperature annealing treatment”), for example, for about one hour, after an oxide semiconductor is deposited so that a layer of the same is formed. When high temperature annealing is carried out in a state in which protrusions as described above are formed, peeling-off or cracks tend to occur to the light-transmitting film. In the above-described configuration, the formation of protrusions is suppressed, whereby cracks or peeling-off hardly occur to the insulating light-transmitting film in a step of performing high temperature annealing to an oxide semiconductor laminated above the insulating light-transmitting film.

The embodiments of the present invention encompass a display device that includes the above-described active matrix substrate. For example, the above-described active matrix substrate can be used in a MEMS display, a liquid crystal display, an organic electroluminescence display, and the like.

The display device can further include: a light-shielding film provided between the surface coating film and the insulating light-transmitting film, the light-shielding film having a plurality of openings; a shutter mechanism part formed in an upper layer with respect to the thin film transistor; and a backlight provided so as to be opposed to the substrate, with the shutter mechanism part being interposed between the backlight and the insulating substrate. The shutter mechanism part can include a shutter body that controls an amount of light from the backlight that passes through the openings provided in the light-shielding film. With this configuration, a MEMS display that controls light to be displayed, by controlling operations of the mechanical shutters, can be provided. By providing a light-shielding film between the insulating substrate and the insulating light-transmitting film, display properties can be improved. Further, lines laminated on the insulating light-transmitting film are prevented from becoming disconnected or having high resistances.

The display device may further include: a counter substrate opposed to the active matrix substrate; and a liquid crystal layer provided between the active matrix substrate and the counter substrate. This allows a liquid crystal display device to be formed.

The display device may further include an organic EL element connected to the thin film transistors. This allows an organic electroluminescence display to be formed.

The embodiments of the present invention also encompass a method for manufacturing an active matrix substrate including thin film transistors arranged in matrix. The method includes the steps of: forming a surface coating film that covers at least a part of a surface of an insulating substrate; forming an insulating light-transmitting film layer on the substrate including the surface coating film; forming the thin film transistors on the insulating light-transmitting film; forming lines on the insulating light-transmitting film, the lines being electrically connected to the thin film transistors; and forming lead-out lines that are electrically connected to the lines and intersect with an end of the insulating light-transmitting film, in a peripheral portion of the insulating substrate, when viewed in the direction vertical to the substrate. In the step of forming the insulating light-transmitting film, an etching treatment is performed in patterning of the insulating light-transmitting film. In the etching treatment, in the peripheral portion of the insulating substrate, a first area where the insulating light-transmitting film is removed, and a second area where the insulating light-transmitting film is left to remain, are formed. In the etching treatment, etching is performed so that, in the first area, the surface coating film is left to remain at least in vicinity of an outer circumference end of the insulating light-transmitting film, which forms the second area. In the step of forming the lead-out lines, the lead-out lines are formed so as to intersect with the outer circumference end of the insulating light-transmitting film.

The light-shielding area of the insulating light-transmitting film can be provided at a position that overlaps with the thin film transistor when viewed in a direction vertical to the insulating substrate.

In the above-described configuration, external light that is incident, having passed through the insulating substrate, is blocked by the light-shielding area, and is prevented from reaching the thin film transistor. Accordingly, it is possible to prevent threshold value properties and the like of the thin film transistor from deteriorating due to external light.

The light-shielding area can be provided in an area where a plurality of pixels are arranged, from which the light-transmitting area is excluded, when viewed in the direction vertical to the insulating substrate.

This makes it possible to more efficiently block light incident from the insulating substrate side. Further, this makes it possible to prevent external light advancing from the insulating substrate into the active matrix substrate from being reflected on metal films such as lines or thin film transistors of the active matrix substrate toward the display viewing side. This makes it possible to suppress reductions in contrast caused by reflection of external light.

The shutter mechanism part can include, for example: a shutter body that is movable according to a voltage applied thereto; a shutter beam that is electrically connected with the shutter body, and is elastically deformed according to a voltage applied thereto so as to make the shutter body movable; a shutter beam anchor that is electrically connected with the shutter beam and supports the shutter beam; a driving beam opposed to the shutter beam; and a driving beam anchor that is electrically connected with the driving beam and supports the driving beam. The thin film transistor, for example, can be electrically connected to the driving beam anchor.

In the peripheral portion of the insulating substrate, an angle formed between the surface of the insulating substrate and the end surface of the insulating light-transmitting film can be smaller than 20°.

The above-described display device may further include a counter substrate that is arranged so as to be opposed to the insulating substrate, and a ring-shaped sealing member that bonds peripheral portions of the insulating substrate and the counter substrate. In this case, in the peripheral portion of the insulating substrate, the sealing member can be arranged so as not to overlap the end of the insulating light-transmitting film.

As described above, the thin film transistors may include an oxide semiconductor. The thin film transistors, which include an oxide semiconductor, tend to deteriorate due to light; for example, threshold value properties thereof tend to vary due to light. With the light-shielding film formed in at least areas that overlap the thin film transistors, as is the case with the above-described configuration, however, light is prevented from being projected to the thin film transistors from the substrate side. The above-described configuration is therefore preferable in a case where the thin film transistors are formed with oxide semiconductor films.

The following describes preferred embodiments of the present invention in detail, while referring to the drawings. The drawings referred to in the following description illustrate, for convenience of description, only the principal members necessary for describing the present invention, among the constituent members in the embodiments, in a simplified manner. The present invention, therefore, may include arbitrary constituent members that are not described in the descriptions of the following embodiments. Further, the dimension ratios of the constituent members illustrated in the drawings do not necessarily indicate the real sizes, the real dimension ratios, etc.

### Embodiment 1

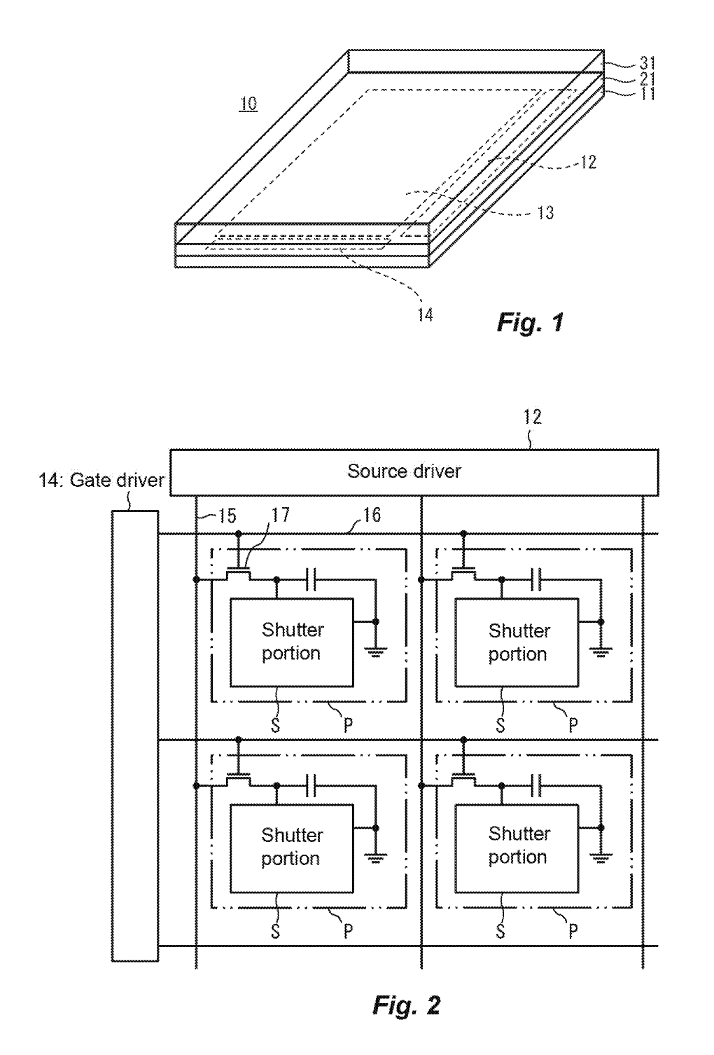

FIG. 1 is a perspective view illustrating an exemplary schematic configuration of a display device in the present embodiment. FIG. 2 is an equivalent circuit diagram of the display device 10. The display device 10 illustrated in FIG. 1 is a transmission type MEMS display. The display device 10 has a configuration in which a first substrate 11A second substrate 21, and a backlight 31 are laminated in the stated order. The first substrate 11 is an exemplary active matrix substrate.

The first substrate 11 includes a display region 13 in which pixels P for displaying images are arranged, as well as a source driver 12 and a gate driver 14 that supply signals for controlling the transmission of light of each pixel P. The second substrate 21 is provided so as to cover a backlight surface of the backlight 31.

The backlight 31 includes, for example, a red color (R) light source, a green color (G) light source, and a blue color (B) light source so as to project back light to each pixel P. The backlight 31, based on backlight control signals input thereto, causes a predetermined light source to emit light.

As illustrated in FIG. 2, a plurality of data lines 15 and a plurality of gate lines 16 that extend intersecting with the data lines 15 are provided on the first substrate 11. The pixels P are defined by the data lines 15 and the gate lines 16. The pixels P are provided at positions opposed to points of intersection between the data lines 15 and the gate lines 16, respectively. At each pixel P, a shutter portion S and a TFT 17 that controls the shutter portion S are provided. The TFT 17 is connected to the data line 15 and the gate line 16. The shutter portion S is an exemplary shutter mechanism.

Each data line 15 is connected to the source driver 12, and each gate line 16 is connected to the gate driver 14. The gate driver 14 sequentially inputs, to each gate line 16, a gate signal that switches the gate line 16 to a selected state or a non-selected state, thereby scanning the gate lines 16. The source driver 12 inputs data signals to each data line 15 in synchronization with the scanning of the gate lines 16. This causes desired signal voltages to be applied to respective shutter portions S of the pixels P connected to the selected gate line 16.

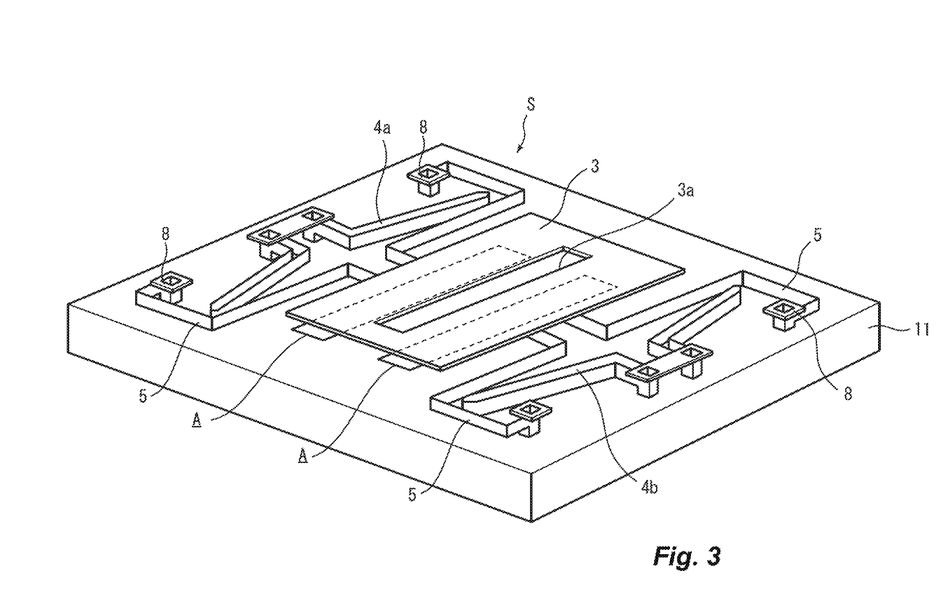

FIG. 3 is a perspective view illustrating a detailed exemplary configuration of the shutter portion S at one pixel P. The shutter portions S includes a shutter body 3, a first electrode portion 4a, a second electrode portion 4b, and a shutter beam 5.

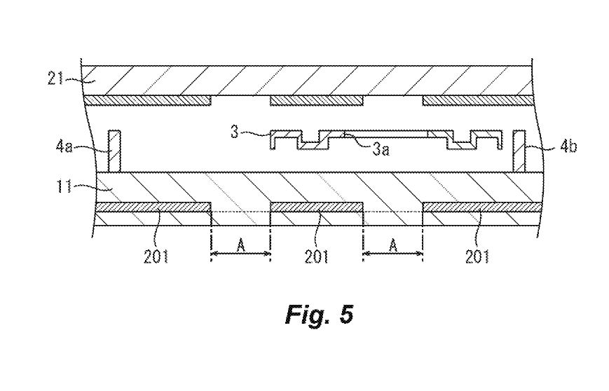

The shutter body 3 has a plate-like shape. In FIG. 3, for convenience sake of illustration, the shutter body 3 is illustrated as having a flat plate shape, but actually, as illustrated in the cross-sectional views in FIG. 5 to be described below, the shutter body 3 has a shape having folds in the lengthwise direction of the shutter body 3. The direction vertical to the lengthwise direction (long side direction) of the shutter body 3, that is, the short side direction, is a direction in which the shutter body 3 is driven (movement direction). The shutter body 3 has an opening 3a that extends in the lengthwise direction. The opening 3a is formed in a rectangular shape having long sides extending in the lengthwise direction of the shutter body 3.

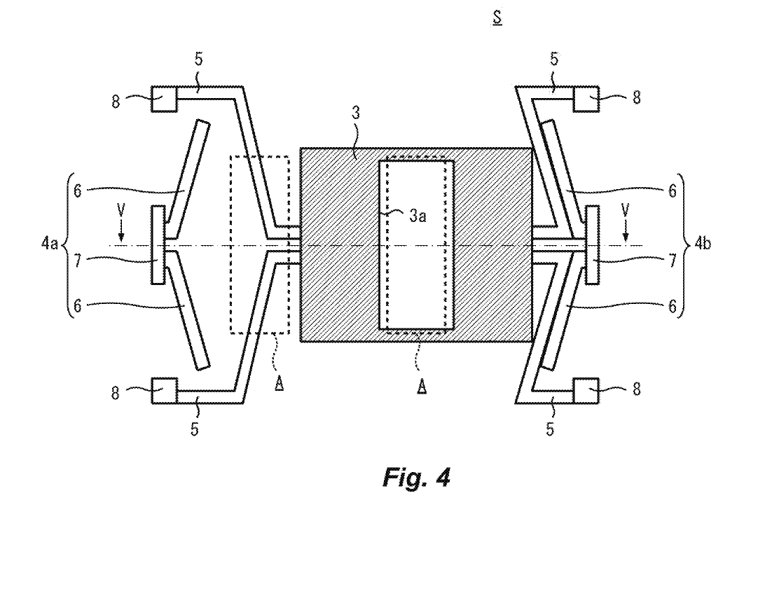

As illustrated in FIG. 4, the first electrode portion 4a and the second electrode portion 4b are arranged on both sides of the shutter body 3, the sides being sides in the driving direction. Each of the first electrode portion 4a and the second electrode portion 4b has two driving beams 6 and a driving beam anchor 7. The two driving beams 6 are arranged so as to be opposed to the shutter beams 5, respectively. The driving beam anchor 7 is electrically connected with the two driving beams 6. Further, the driving beam anchor 7 supports the two driving beams 6. A predetermined voltage is applied to the first electrode portion 4a and the second electrode portion 4b, as is described below.

The shutter body 3 is connected to one end of each shutter beam 5. The other end of each shutter beam 5 is connected to the shutter beam anchor 8 fixed to the first substrate 11. The shutter beams 5 are connected to end portions in the driving direction of the shutter body 3, respectively. The shutter beams 5 extend from the portions connected with the shutter body 3 outward, and further extend along the end portions in the driving direction of the shutter body 3, to be connected to the shutter beam anchors 8. The shutter beams 5 have flexibility. The shutter body 3 is supported in a state movable with respect to the first substrate 11 By the shutter beam anchors 8 fixed to the first substrate 11 And the shutter beams 5 that have flexibility and that connect the shutter beam anchors 8 and the shutter body 3. Further, the shutter body 3 is electrically connected through the shutter beam anchors 8 and the shutter beams 5 to the lines provided on the first substrate 11.

The first substrate 11 has light-transmitting areas A as illustrated in FIG. 3. The light-transmitting area A has, for example, a rectangular shape corresponding to the opening 3a of the shutter body 3. For example, two light-transmitting areas A are provided with respect to one shutter body 3. The two light-transmitting areas A are arranged so as to be arrayed in the short side direction of the shutter body 3. In a case where no electric force is exerted between the shutter body 3 and the first electrode portion 4a, and between the shutter body 3 and the second electrode portion 4b, the opening 3a of the shutter body 3 is in a state of not overlapping the light-transmitting area A.

In the present embodiment, the driving circuit that controls the shutter portions S supplies potentials having different polarities to the first electrode portion 4a and the second electrode portion 4b, respectively, the polarities varying with time. In this case, the driving circuit can control the polarity of the potential of the first electrode portion 4a and the polarity of the potential of the second electrode portion 4b in such a manner that these polarities are different at all times. Further, the driving circuit that controls the shutter portions S supplies a fixed potential having a positive polarity or a negative polarity to the shutter body 3.

The following description describes an exemplary case where a potential at a high (H) level is supplied to the shutter body 3. When the driving beam 6 of the first electrode portion 4a has a potential at H level and the driving beam 6 of the second electrode portion 4b has a potential at low (L) level, electrostatic force causes the shutter body 3 to move toward the side of the second electrode portion 4b having a potential at L level. As a result, as illustrated in FIGS. 4 and 5, the opening 3a of the shutter body 3 overlaps the light-transmitting area A, whereby the state shifts to an opened state in which light from the backlight 31 passes therethrough to the first substrate 11 side.

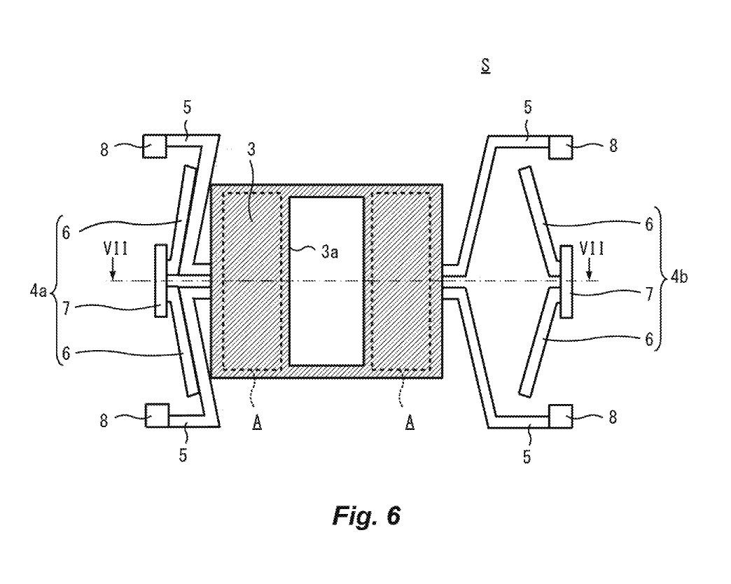

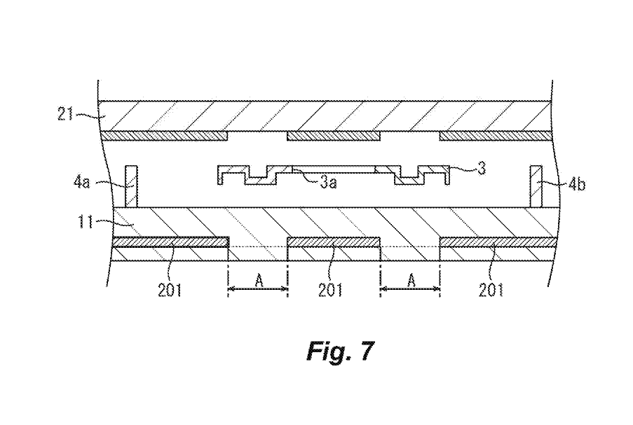

When the potential of the first electrode portion 4a is at L level and the potential of the second electrode portion 4b is at H level, the shutter body 3 moves toward the first electrode portion 4a side. Then, as illustrated in FIGS. 6 and 7, the portion other than the opening 3a of the shutter body 3 overlaps the light-transmitting area A of the first substrate 11. In this case, the state shifts to a closed state in which light from the backlight 31 does not pass toward the first substrate 11 side. In the shutter portions S of the present embodiment, therefore, the shutter body 3 is moved by controlling the potentials of the shutter body 3, the first electrode portion 4a, and the second electrode portion 4b, so as to switch the opened state and the closed state of the light-transmitting area A. In a case where a potential at L level is supplied to the shutter body 3, the shutter body 3 makes an operation reverse to that described above.

### (Exemplary Configuration of First Substrate)

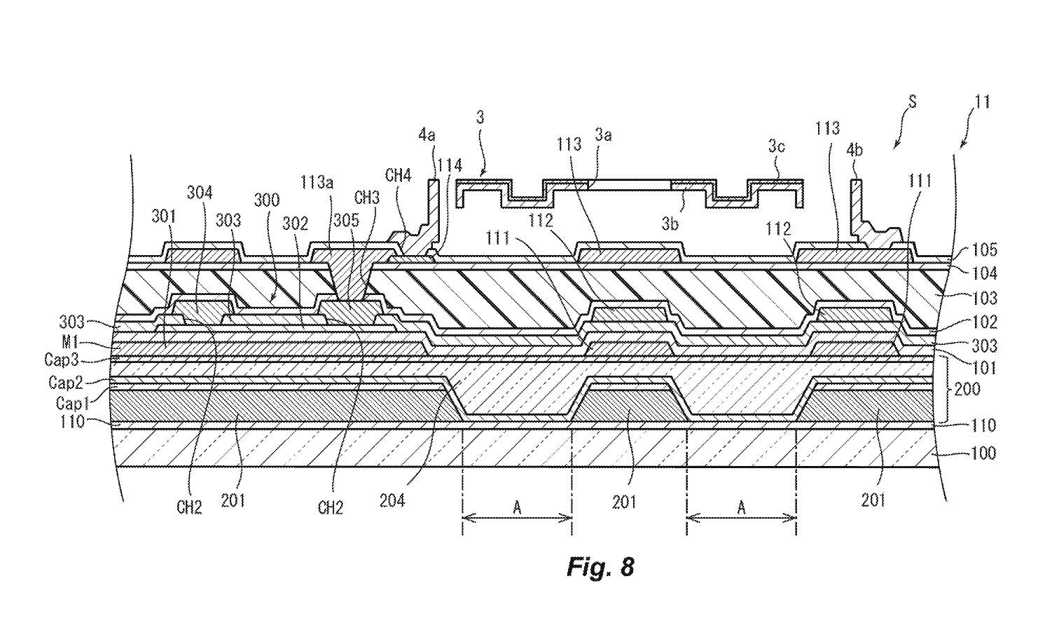

FIG. 8 is a cross-sectional view illustrating an exemplary configuration of the first substrate 11.

The first substrate 11 has such a configuration that a surface coating film 110, a light-shielding layer 200, TFTs 300, and shutter portions S are formed on the translucent substrate 100 (an exemplary insulating substrate). In FIG. 8, one TFT is illustrated, but actually, a plurality of TFTs may be included in a single pixel P. The light-shielding layer 200 includes a light-shielding film 201, a first transparent insulating film Cap1, a second transparent insulating film Cap2, a light-transmitting film 204, and a third transparent insulating film Cap3. Each TFT 300 includes a gate electrode 301, a semiconductor film 302, an etching stopper layer 303, a source electrode 304, and a drain electrode 305.

The translucent substrate 100 can be formed with, for example, glass or a resin. From the viewpoint of heat-resisting properties, it is preferable to use glass. In a case where the translucent substrate 100 is a glass substrate, for example, non-alkali glass, alkali glass, or the like can be used as a material for the substrate. The translucent substrate 100 is an exemplary insulating substrate.

The surface of the translucent substrate 100 is covered with a surface coating film 110. The surface coating film 110 can be provided so as to cover an entire surface of the translucent substrate 100. The surface coating film 110 is formed with a transparent insulating film. For example, the surface coating film 110 can be formed with an inorganic insulating film made of SiO₂, SiNₓ, or the like. In a case where the translucent substrate 100 is a glass substrate, the surface coating film 110 is preferably an SiO₂ film from the viewpoint of the refractive index.

The light-shielding layer 200 is provided on the translucent substrate 100 including the surface coating film 110. More specifically, the light-shielding layer 200 is arranged in a layer between the shutter portions S and the translucent substrate 100. Further, the light-shielding layer 200 is arranged in the layer between the layer in which the TFTs 300 are arranged and the translucent substrate 100. In the light-shielding layer 200, the part of the light-shielding film 201 serves as the light-shielding area.

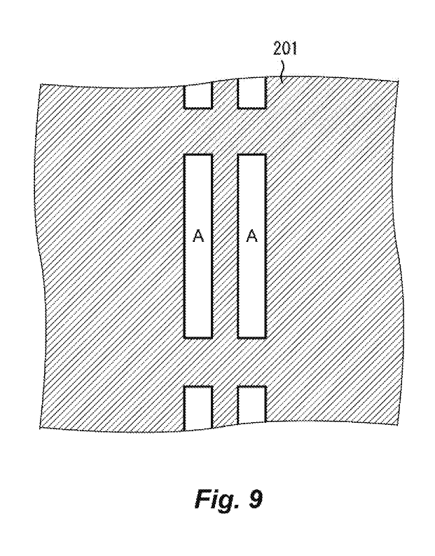

The light-shielding film 201 is provided on the surface coating film 110. FIG. 9 illustrates an exemplary arrangement of the light-shielding film 201 when it is viewed in a direction vertical to the translucent substrate 100. In the example illustrated in FIG. 9, the light-shielding film 201 is formed so as to cover the display region 13 other than the light-transmitting areas A. This makes it possible to prevent external light that has advanced from the display viewing side into the display device 10 from advancing into the second substrate 21 side beyond the light-shielding film 201. The light-shielding area formed by the light-shielding film 201, however, is not limited to the example illustrated in FIG. 9. For example, at least an area superposed on the gate lines G and the data lines D when viewed in a direction vertical to the translucent substrate 100 can be the light-shielding area.

The light-shielding film 201 can be formed with a material that hardly reflects light. This makes it possible to prevent external light that has advanced from the display viewing side into the display device 10 from being reflected by the light-shielding film 201 and going back to the display viewing side. Further, the light-shielding film 201 can be formed with the material having a high resistance. This makes it possible to prevent a great parasitic capacitance from being generated between the light-shielding film 201 and conductive films forming the TFTs 300 and the like. Still further, since the light-shielding film 201 is formed prior to the TFT manufacturing process, a material that has less influence to TFT properties in subsequent processing operations in the TFT manufacturing process, and that withstand the processing operations in the TFT manufacturing process is preferably selected for a material for light-shielding film 201. Examples of the material of the light-shielding film 201 that satisfy such requirements include, for example, a high-melting-point resin film (polyimide, etc.) and a spin-on-glass (SOG) film that are colored in a dark color. Still further, the light-shielding film 201, for example, can contain carbon black so as to be colored in a dark color.

The light-transmitting film 204 is an insulating film that is provided so as to cover the light-shielding film 201 between the translucent substrate 100 and the shutter portions S. Further, the light-transmitting film 204 is provided in the layer between the translucent substrate 100 and the layer where the TFTs 300 are arranged, like the light-shielding film 201. The light-transmitting film 204 is filled in areas where the light-shielding film 201 is not provided when viewed in the direction vertical to the translucent substrate 100, whereby steps formed due to the light-shielding film 201 are eliminated. Still further, the light-transmitting film 204 covers an entirety of the display region 13 including the light-shielding film 201, thereby flattening the surface of the film covering the light-shielding film 201. The light-transmitting film 204 is an exemplary insulating light-transmitting film.

The light-transmitting film 204 can be formed with, for example, a coating-type material. The coating-type material is a material that is applicable in a liquid state. The coating-type material, in a state of being contained in a coating liquid, is spread over a surface on which a film is to be formed, and is cured by a heat treatment or the like, whereby a film of the same is formed. For example, a solution in of the coating-type material dissolved in a solvent is dropped on the surface on which a film is to be formed, and the surface is rotated, whereby the coating-type material can be applied on the surface. In this case, the coating-type material is applied so as to reducing protrusions and recesses of the surface. The solvent of the solution thus applied is evaporated by a heat treatment or the like, whereby a film having a flat surface is formed.

As the coating-type material used for forming the light-transmitting film 204, a material for a transparent high-melting-point resin film (polyimide, etc.), a material for an SOG film, or the like, can be used. The SOG film is, for example, a film that is formed with use of a solution obtained by dissolving a silicon compound in an organic solvent, and contains silicon dioxide as a principal component. Examples of a material that can be used for forming the SOG film include: inorganic SOG containing silanol (Si(OH)₄) as a principal component; organic SOG containing silanol having alkyl groups (RₓSi(OH)₄₋ₓ (R: alkyl group)) as a principal component; and a sol-gel material in which an alkoxide of silicon or a metal is used. Examples of inorganic SOG include a hydrogen silsesquioxane (HSQ)-based material. Examples of organic SOG include a methyl silsesquioxane (MSQ)-based material. Examples of the sol-gel material include TEOS (tetraethoxysilane). By applying such a material and firing the same, an SOG film can be formed. Materials for SOG films are not limited to those examples described above. Examples of the film forming method by material application include spin coating, and slit coating.

By forming the light-transmitting film 204 with a coating-type material, protrusions and recesses formed during the pattern of the light-shielding film 201 can be flattened easily. When the patterning is performed in the process for manufacturing the TFTs 300, therefore, the pooling of liquid such as resist or the like can be eliminated, whereby excellent patterning accuracy can be achieved. In this way, the light-transmitting film 204 can be made a flattening film.

Further, by forming the light-transmitting film 204 with a coating-type material, a sufficient thickness of the light-transmitting film 204 (the thickness of portions thereof under which the light-shielding film 201 is formed) can be ensured easily. For example, the thickness of the light-transmitting film 204 can be increased to about 1.0 to 3 μm. For example, in a case where a material having a low resistance is used for forming the light-shielding film 201, a sufficient distance between the light-shielding film 201 and a conductive film that forms the TFTs 300 (for example, the gate electrodes 301 and the lines 111) can be ensured by the light-transmitting film 204. This makes it possible to suppress parasitic capacitance generated between the light-shielding film 201 and electrodes or lines of the TFTs 300.

In this way, in the present embodiment, the light-shielding layer 200 is provided between the translucent substrate 100 and the shutter portions S. The light-shielding layer 200 includes the light-shielding film 201, and the light-transmitting film 204 that covers the light-shielding film 201. On the light-transmitting film 204, the TFTs 300 for controlling the shutter portions S, and the lines are formed. With the light-transmitting film 204 thus formed with a coating material, the properties of the TFTs 300 are prevented from deteriorating due to steps formed due to the light-shielding film 201, parasitic capacitance, and the like.

In the example illustrated in FIG. 8, the first transparent insulating film Cap1 is provided on the upper surface of the light-shielding film 201. The second transparent insulating film Cap2 is provided so as to cover the light-shielding film 201 and the first transparent insulating film Cap1. On the second transparent insulating film Cap2, the light-transmitting film 204 is provided. In other words, the first transparent insulating film Cap1 and the second transparent insulating film Cap2 are provided between the light-shielding film 201 and the light-transmitting film 204. The first transparent insulating film Cap1 thus provided makes it possible to achieve improved wettability and adhesiveness with a resist material when the light-shielding film 201 is patterned. In addition, since the second transparent insulating film Cap2 is provided so as to cover the upper and side surfaces of the light-shielding film 201, it is possible to prevent a dark color material such as carbon black from being oxidized by high temperature annealing and becoming transparent.

In the display region 13, the third transparent insulating film Cap3 is provided so as to cover the light-transmitting film 204. The third transparent insulating film Cap3 makes it possible to achieve improved wettability and adhesiveness with a resist material when the light-transmitting film 204 is patterned.

On the third transparent insulating film Cap3, the gate electrodes 301 and the lines 111 Are formed. The gate electrodes 301 and the line 111 Are formed with first conductive films M1. Further, the gate lines 16 (see FIG. 2) can be formed with the first conductive films M1. The first conductive film M1 is formed in an area that overlaps with the light-shielding film 201 in the direction vertical to the translucent substrate 100. A gate insulating film 101 is formed so as to cover the gate electrodes 301 and the lines 111 By providing the third transparent insulating film Cap3, the fixability of the light-transmitting film 204 with the first conductive film M1 or the gate insulating film 101 can be improved.

The materials for the first to third transparent insulating films Cap1 to Cap3 are not limited particularly. For example, materials that provide inorganic insulating films can be used. Additionally, as materials for the first to third transparent insulating films Cap1 to Cap3, materials with which films can be formed by CVD can be used.

At a position opposed to the gate electrode 301 with the gate insulating film 101 being interposed therebetween, the semiconductor film 302 is formed. The semiconductor film 302 can be formed with an oxide semiconductor. The semiconductor film 302 may contain, for example, at least one kind of metal element among In, Ga, and Zn. In the present embodiment, the semiconductor film 302 contains, for example, an In—Ga—Zn—O-based semiconductor. Here, the In—Ga—Zn—O-based semiconductor is a ternary oxide of indium (In), gallium (Ga), and zinc (Zn), in which the ratio (composition ratio) of In, Ga, and Zn is not limited particularly, and may be, for example, In:Ga:Zn=2:2:1, In:Ga:Zn=1:1:1, In:Ga:Zn=1:1:2 or the like. Such a semiconductor film 302 can be formed with an oxide semiconductor film that contains an In—Ga—Zn—O-based semiconductor. The channel-etch type TFT having an active layer that contains an In—Ga—Zn—O-based semiconductor is referred to as “CE-InGaZnO-TFT” in some cases. The In—Ga—Zn—O-based semiconductor may be amorphous, or alternatively, may be crystalline. The crystalline In—Ga—Zn—O-based semiconductor is preferably a crystalline In—Ga—Zn—O-based semiconductor in which the c-axis is aligned approximately vertically to the layer surfaces.

The semiconductor layer 302 may contain another oxide semiconductor instead of the In—Ga—Zn—O-based semiconductor. More specifically, the semiconductor layer 302 may contain, for example, a Zn—O-based semiconductor (ZnO), an In—Zn—O-based semiconductor (IZO (registered trademark)), a Zn—Ti (titanium)-O-based semiconductor (ZTO), a Cd (cadmium) —Ge (germanium)-O-based semiconductor, a Cd—Pb (lead)-O-based semiconductor, a CdO (cadmium oxide)-Mg (magnesium)-Zn—O-based semiconductor, an In—Sn (tin)-Zn—O-based semiconductor (for example, In₂O₃—SnO₂—ZnO), or an In—Ga (gallium)-Sn—O-based semiconductor.

The etching stopper layer 303 is provided so as to cover the semiconductor film 302. In a part of an area of the etching stopper layer 303 overlapping the semiconductor film 302, two contact holes CH2 are provided. At the positions corresponding to the contact holes CH2 on the semiconductor film 302, the source electrode 304 and the drain electrode 305 are provided. The source electrode 304 and the drain electrode 305 are connected to the semiconductor film 302 through the two contact holes CH2, respectively. In other words, on the semiconductor film 302, the source electrode 304 and the drain electrode 305 are arranged so as to be opposed to each other in the direction vertical to the lamination direction.

The source electrodes 304 and the drain electrodes 305 are formed with second conductive films M2. The second conductive films M2 also form the lines 112 and the like, in addition to the source electrodes 304 and the drain electrodes 305 of the TFTs 300. Further, it is also possible to form the data lines 15 (see FIG. 2) with the second conductive films M2.

The source electrodes 304 and the drain electrodes 305 are covered with a passivation film 102. The passivation film 102 is further covered with a flattening film 103 and a passivation film 104.

In the passivation film 102, the flattening film 103, and the passivation film 104, there are provided contact holes CH3 that reach the drain electrodes 305. On the passivation film 104, lines 113 are formed. Parts 113a of the lines 113 are provided so as to cover surfaces of the contact holes CH3, and are electrically connected with drain electrodes 305. The lines 113 are formed with third conductive films M3. The lines 113 are connected to the first electrode portions 4a, the second electrode portions 4b, the shutter bodies 3 and the like of the shutter portions S. The parts 113a of the lines 113 may be electrically connected with the transparent conductive films 114 provided on the surface of the passivation film 104. The lines 113 are covered with a passivation film 105.

On the passivation film 105, there are provided the shutter portions S. The configuration of the shutter portion S is as mentioned above. The shutter body 3, however, has a configuration in which the shutter main body 3b on the translucent substrate 100 side and a metal film 3c are laminated.

### (Exemplary Configuration in Vicinity of End of Light-Transmitting Film)

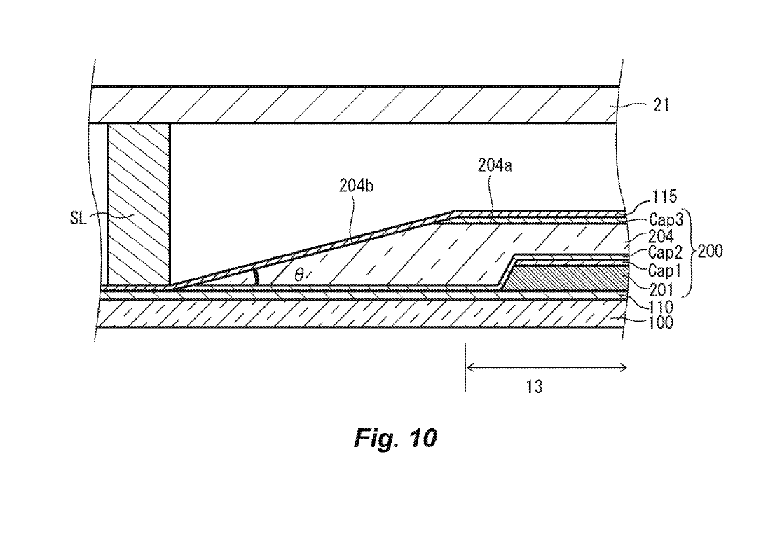

FIG. 10 is a cross-sectional view illustrating an exemplary configuration in the vicinity of an end of the light-transmitting film 204. In the example illustrated in FIG. 10, the first substrate 11 And the second substrate 21 are bonded to each other at peripheral portions of the display region 13, with a sealing member SL. A space is encapsulated between the substrates 11, 21, with the sealing member SL. The sealing member SL is arranged on an outer circumference side with respect to the light-transmitting film 204, so as not to be in contact with an end surface 204b of the light-transmitting film 204. In other words, the end surface 204b of the light-transmitting film 204 is positioned on an inner side with respect to the sealing member SL (on the display region 13 side). Thus, the sealing member SL is provided at such a position that the sealing member SL does not overlap with the end of the light-shielding layer 200. When viewed in the direction vertical to the translucent substrate 100, the sealing member SL is arranged in a ring form surrounding the light-shielding layer 200.

In the example illustrated in FIG. 10, since the surface coating film 110 is provided over an entire surface of the translucent substrate 100, the surface coating film 110 overlaps with the sealing member SL when viewed in a direction vertical to the translucent substrate 100. In contrast, the surface coating film 110 can be arranged on an inner side with respect to the sealing member SL.

On an end surface 204b of the light-transmitting film 204 at the end of the light-shielding layer 200, lead-out lines 115 are formed. The lead-out lines 115 are parts of lines connected to the TFT 300 formed in the display region 13. For example, the gate electrodes 301 of the TFTs 300, or the lines 111 are connected with the lead-out lines 115. More specifically, a plurality of the data lines 15 or the gate lines 16 (FIG. 2) are connected to the lead-out lines 115. In this way, at least parts of lines connected to the TFTs 300 in the display region 13 are led out to the outside of the display region 13 and the sealing member SL, by the lead-out lines 115 passing over the end of the light-shielding layer 200. The lead-out line 115 can be connected to at least one of the first conductive film M1, the second conductive film M2, and the third conductive film M3.

The light-transmitting film 204, in an outer peripheral portion of the display region 13, the film thickness gradually decreases, in such a direction as the proximity to the display region 13 decreases. The surface of the light-transmitting film 204 in the outer peripheral portion of the display region 13, that is, the end surface 204b, forms a surface inclined with respect to the translucent substrate 100. The end surface 204b of the light-transmitting film 204 is inclined with respect to the surface of the translucent substrate 100 in such a manner that the height thereof from the translucent substrate 100 decreases as the proximity to the display region 13 where the pixels are arranged decreases.

The angle θ formed between end surface 204b of the light-transmitting film 204 and the translucent substrate 100 is preferably smaller than 20°. For example, the angle θ can be set to 3° to 10°, that is, in a range of 3° to 10° both inclusive.

Since the thickness of the light-transmitting film 204 is, for example, 1.0 μm or more, the step formed by the light-transmitting film 204 becomes greater in the outer peripheral portion of the pattern of the light-transmitting film 204. Here, in the outer peripheral portion of the light-transmitting film 204, the end surface 204b of the light-transmitting film 204 can be formed as a surface inclined with respect to the translucent substrate 100, and the angle θ formed between the inclined surface and the translucent substrate 100 can be smaller than 20°. This causes disconnection to hardly occur to lines and the like getting onto the light-transmitting film 204 from the surface of the translucent substrate 100 (in FIG. 10, lead-out lines 115).

Further, on the surface of the translucent substrate 100, the surface coating film 110 is provided. This causes protrusions to hardly be formed at the end of the light-shielding layer 200, in the step of forming the light-shielding layer 200. Further, this also makes it possible to improve the application properties of the light-shielding film 204. If no surface coating film is provided, in a step of patterning a light-shielding layer on the substrate, surface portions of the substrate in areas from which the light-shielding layer is removed would highly possibly be reduced by over-etching. In this case, in the vicinity of the end of the remaining light-shielding layer, a plurality of needle-like protrusions are formed on surfaces of the light-shielding layer and the substrate in some cases. Particularly, in a case where the substrate is a glass substrate and the light-shielding layer contains a coating-type material such as SOG, protrusions tend to be formed.

To cope with this, as is the case with the present embodiment, the surface of the translucent substrate 100 is covered with the surface coating film 110, whereby the translucent substrate 100 can be prevented from being exposed at the end of the light-transmitting film 204 when the light-transmitting film 204 is etched. This suppresses the formation of protrusions.

The surface coating film 110 can be formed with a material that is etched to a lower degree in the etching performed during patterning for forming the end of the light-transmitting film 204, as compared with the material of the end of the light-transmitting film 204. This makes it easier to allow the surface coating film 110 to remain in an area in contact with the outer circumference end of the light-transmitting film 204, when the light-transmitting film 204 is etched.

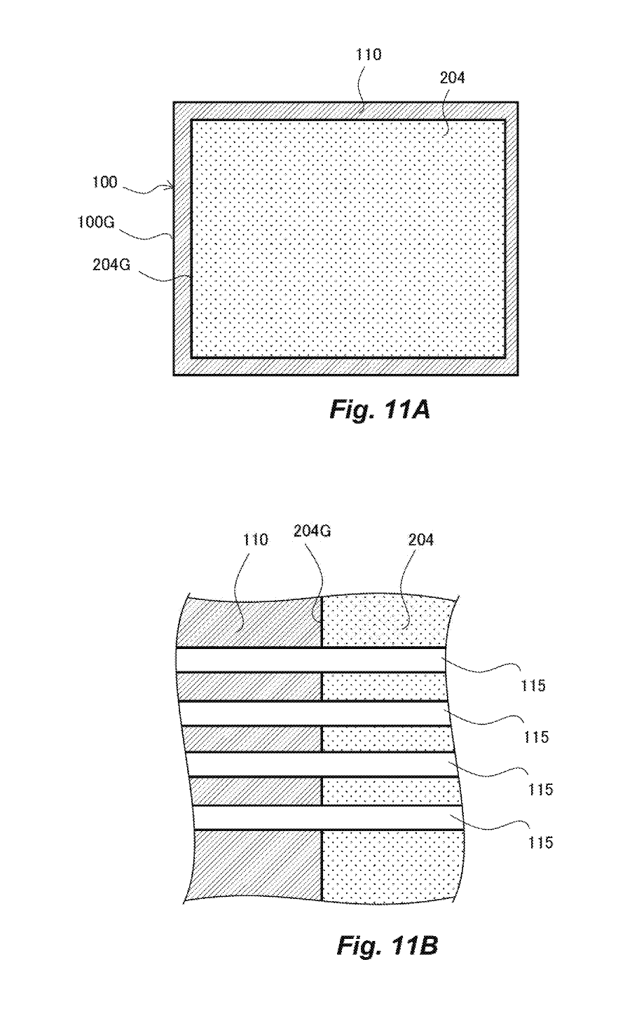

FIG. 11A illustrates an exemplary area where the light-transmitting film 204 is formed when viewed in a direction vertical to the translucent substrate 100 (that is, the direction vertical to the display screen). FIG. 11B is a plan view illustrating the vicinity of the end of the light-shielding layer 200 in FIG. 10, when viewed in the direction vertical to the translucent substrate 100. In the example Illustrated in FIG. 11A, an area where the light-transmitting film 204 is not formed (an exemplary first area) is provided in the peripheral portion of the translucent substrate 100 (the area indicated by oblique hatching in FIG. 11A) when viewed in the direction vertical to the translucent substrate 100 (hereinafter referred to as “when viewed in plan view”). The peripheral portion of the translucent substrate 100 is an area in contact with the outer circumference end 100G of the translucent substrate 100 (the area indicated by oblique hatching in FIG. 11A) when viewed in plan view. The outer circumference end 204G of the light-transmitting film 204 is positioned on an inner side with respect to the outer circumference end 100G of the translucent substrate 100 when viewed in plan view. In other words, when viewed in plan view, the area where the light-transmitting film 204 is formed (an exemplary second area) is arranged on an inner side with respect to the outer circumference end 100G of the translucent substrate 100. In FIG. 11A, the area where the light-transmitting film 204 is provided is indicated by dot hatching.

In a part of the peripheral portion of the translucent substrate 100 (for example, the area to which the lines are led out), the outer circumference end 204G of the light-transmitting film 204 may be arranged on an inner side with respect to the outer circumference end 100G of the translucent substrate 100. In other words, a part of the outer circumference end 100G of the translucent substrate 100 and a part of the outer circumference end 204G of the light-transmitting film 204 may overlap with each other when viewed in plan view.

The surface coating film 110 is formed in both of the area where the light-transmitting film 204 is not formed (the first area) and the area where the light-transmitting film 204 is formed (the second area). In other words, the surface coating film 110 is formed extending from between the light-transmitting film 204 and the translucent substrate 100, to the area where the light-transmitting film 204 is not formed. The surface coating film 110 is provided over the outer circumference end 204G of the light-transmitting film 204, that is, a boundary between the first area and the second area, when viewed in plan view.

As illustrated in FIG. 11B, the surface coating film 110 is provided in the area where the light-transmitting film 204 is not provided, in a part in contact with the outer circumference end of the light-transmitting film 204 intersecting with the lead-out lines 115, when viewed in plan view. In this way, in the area from which the light-transmitting film 204 is removed on the translucent substrate 100, the surface coating film 110 is left to remain in the part in contact with the outer circumference end of the light-transmitting film 204. The lead-out lines 115 are arranged so as to pass over the outer circumference end of the light-transmitting film 204 that the surface coating film 110 is in contact with. In other words, the surface coating film 110 is formed at least in an area that includes the outer circumference end of the light-transmitting film 204 that intersects with the lead-out lines 115

### (Manufacturing Method)

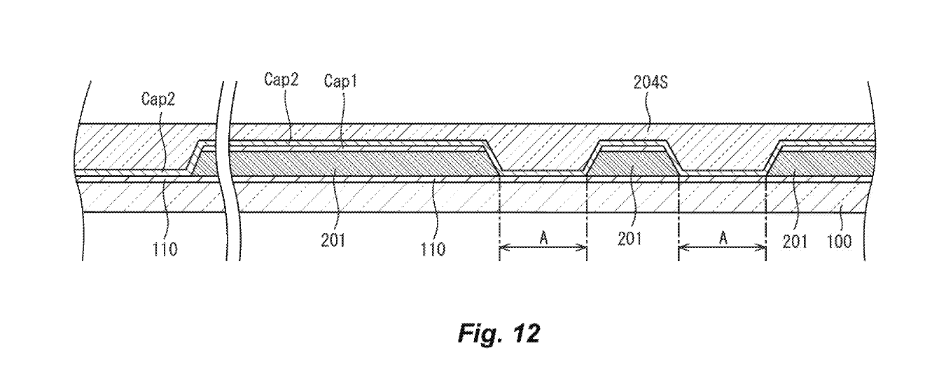

FIGS. 12 to 19 illustrate exemplary process for manufacturing the first substrate 11. First, as illustrated in FIG. 12, the translucent substrate 100 is prepared. On the translucent substrate 100, an SiO₂ film for forming the surface coating film 110 is formed by the PECVD method. The temperature during the film formation can be set to, for example, 200° C. to 350° C.

An SOG film for forming the light-shielding film 201 is formed by spin coating on the translucent substrate 100 on which the surface coating film 110 is formed. The SOG film can be also formed by slit coating, other than spin coating. The SOG film is fired for about one hour in an atmosphere at 200 to 350° C. The SOG film for forming the light-shielding film 201 can have a thickness of, for example, 0.5 μm to 1.5 μm.

Subsequently, an SiO₂ film is formed by the PECVD method on the translucent substrate 100 so as to cover the light-shielding film 201. The temperature during the film formation can be, for example, 200° C. to 350° C. The obtained SiO₂ film can have a thickness of, for example, 50 nm to 200 nm.

The SOG film and the SiO₂ film is subjected to an annealing treatment in a nitrogen atmosphere. The temperature at which the annealing treatment is performed is set to, for example, 400° C. to 500° C. The time while the annealing treatment is performed is, for example, about one hour. The annealing treatment may be performed in, for example, a clean dry air (CDA) atmosphere, in place of the nitrogen atmosphere. Here, the annealing is preferably carried out at a temperature at the same level as or higher than the annealing temperature for the oxide semiconductor of the TFTs in the later step. By preliminarily annealing the SOG film for forming the light-shielding film 201, the occurrence of cracks in, or peeling of, the light-shielding film 201 can be suppressed, at the later step of the high temperature annealing in the TFT manufacturing process. Since the SOG film is covered with the SiO₂ film, the dark color material such as carbon black can be prevented from being oxidized by annealing and becoming transparent.

The SOG film and the SiO₂ film are patterned by photolithography. With this, the light-shielding film 201, and the first transparent insulating films Cap1 on the upper surface of the light-shielding film 201 are formed. More specifically, by performing dry etching with use of CF₄ gas and O₂ gas, the light-shielding film 201 and the first transparent insulating films Cap1 can be formed.

Next, an SiO2 film is formed by the PECVD method on the translucent substrate 100 so as to cover the first transparent insulating films Cap1 and light-shielding film 201, whereby a second transparent insulating film Cap2 is formed. The temperature during the film formation can be, for example, 200° C. to 350° C. The obtained SiO₂ film can have a thickness of, for example, 50 nm to 200 nm.

Next, an SOG film 204S for forming the light-transmitting film 204 is formed on the second transparent insulating film Cap2 by spin coating. The SOG film 204S may be also formed by slit coating, other than spin coating. The SOG film 204S has a film thickness of, for example, about 1.0 to 3 μm. Here, the thickness of the SOG film 204S is, for example, at least 0.5 μm, that is, 0.5 μm or more, thicker than the thickness of the light-shielding film 201, which is the SOG film in a lower layer. Then, the SOG film 204S is fired for about one hour in an atmosphere at 200 to 350° C. By patterning the SOG film 204S, the peripheral portion of the outer circumference of the SOG film 204S is removed, whereby the light-transmitting film 204 is formed.

In this patterning, dry etching is carried out. The thickness of the SOG film 204S for forming the light-transmitting film 204 is equal to, or more than, twice the sum of the thickness of the surface coating film 110 and the thickness of the second transparent insulating film Cap2. Accordingly, in a case where the sum of the thickness of the surface coating film 110 (hereinafter abbreviated as “Cap0”) and the thickness of the second transparent insulating film (hereinafter abbreviated as “Cap2”) is significantly smaller as compared with the thickness of the SOG film 204S, there is a high possibility that the surface of the translucent substrate 100 is reduced by dry etching, and protrusions are formed. To cope with this, the sum of thicknesses of Cap0 and Cap2 may be set to such a level that the surface of the translucent substrate 100 is not reduced by dry etching during the patterning of the SOG film 204S. For example, the films can be formed so that the sum of the thicknesses of Cap0 and Cap2 is 10% to 20% of the thickness of the SOG film 204S for forming the light-transmitting film 204. As one example, in a case where the SOG film 204S has a thickness of 2000 nm, Cap0 can be formed to have a thickness of 100 nm, and Cap2 can be formed to have a thickness of 150 nm. The following description describes, for example, a case where the etching rate for etching the SOG film 204S is 12 to 15 nm/sec, and the thickness of the SOG film 204S is 2000 nm. When over-etching is assumed to be 20%, over-etching is carried out for about 27 to 33 seconds. In a case where Cap0 and Cap2 are SiO₂ films, the etching rate for the SiO₂ film is 3 to 5 nm/sec. In this case, Cap0 and Cap2 are reduced to at most about 167 nm in total. If the thicknesses of Cap0 and Cap2 before etching are assumed to be 100 nm and 150 nm, respectively, Cap2 disappears after etching, but Cap0 having a thickness of at least about 83 nm remains. In this way, if the sum of the thicknesses of Cap0 and Cap2 is set to 10% to 20% of the thickness of the SOG film, such a configuration that SiO₂ remains on the translucent substrate and protrusions are not formed can be obtained.

In this dry etching, in an area where the SOG film 204S on the translucent substrate 100 is removed by etching, the surface coating film 110 is left to remain in the end of the remaining SOG film 204S, that is, in the area in contact with the end of the light-shielding layer 200. In other words, the patterning of the SOG film 204S is performed by such etching that the surface coating film 110 remains on the translucent substrate 100.

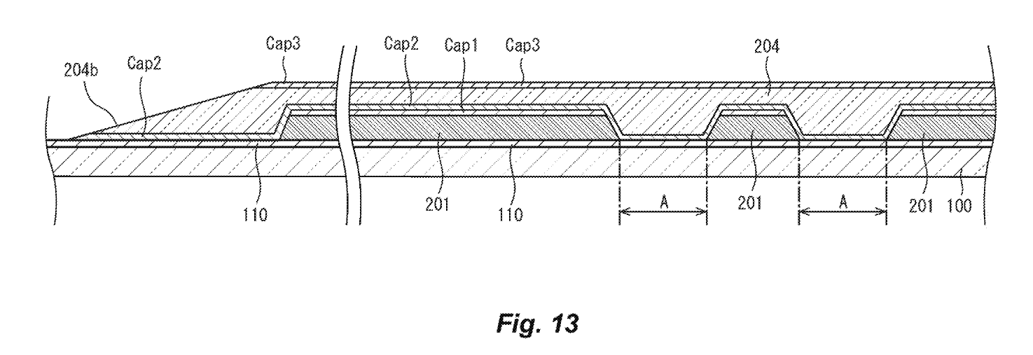

In the patterning of the SOG film 204S, the patterning with use of a gray tone mask or the patterning without use of a mask is performed, whereby a taper shape as illustrated in FIG. 10 and FIG. 13 can be formed at the end of the light-transmitting film 204. In this way, the end surface 204b of the light-transmitting film 204 is formed into an inclined surface having an angle with respect to the translucent substrate 100. The angle of the end surface 204b with respect to the translucent substrate 100 can be set to, for example, 3° or more, and 10° or less. By forming such a taper shape, the occurrence of cracks in the light-transmitting film 204 during high temperature annealing can be suppressed.

Next, an SiO₂ film is formed by the PECVD method so as to cover the light-transmitting film 204. The temperature during the film formation can be set to, for example, 200 to 350° C. The SiO₂ film can have a thickness of, for example, 50 to 200 nm. The SiO₂ film is patterned by photolithography so that the SiO₂ film has a pattern identical to the pattern of the light-transmitting film 204 in the display region 13. This causes the third transparent insulating film Cap3 to be formed on the upper surface of the light-transmitting film 204 (see FIG. 13). More specifically, the third transparent insulating film Cap3 can be formed by performing dry etching with use of CF₄ gas and O₂ gas.

A high temperature annealing treatment is carried out with respect to the third transparent insulating film Cap3 in a nitrogen atmosphere. The temperature at which the annealing treatment is performed can be a temperature at the same level as, or higher than, the annealing temperature for the oxide semiconductor of the TFTs in the later step (for example, 400 to 500° C.). The annealing time is, for example, about one hour. The annealing, however, may be carried out in, for example, a clean dry air (CDA) atmosphere, other than the nitrogen atmosphere. By performing the annealing treatment preliminarily, the occurrence of cracks in the light-transmitting film 204 or peeling-off of the light-transmitting film 204 in a later high temperature annealing step in the TFT manufacturing process is suppressed.

In the above-described example, the SOG film is patterned so that the light-transmitting film 204 is formed, and thereafter, the SiO₂ film is formed and patterned, whereby the third transparent insulating film Cap3 is formed. In contrast, it is also possible to, for example, laminate the SOG film and the SiO₂ film, then pattern these two layers, thereby forming the light-transmitting film 204 and the third transparent insulating film Cap3.

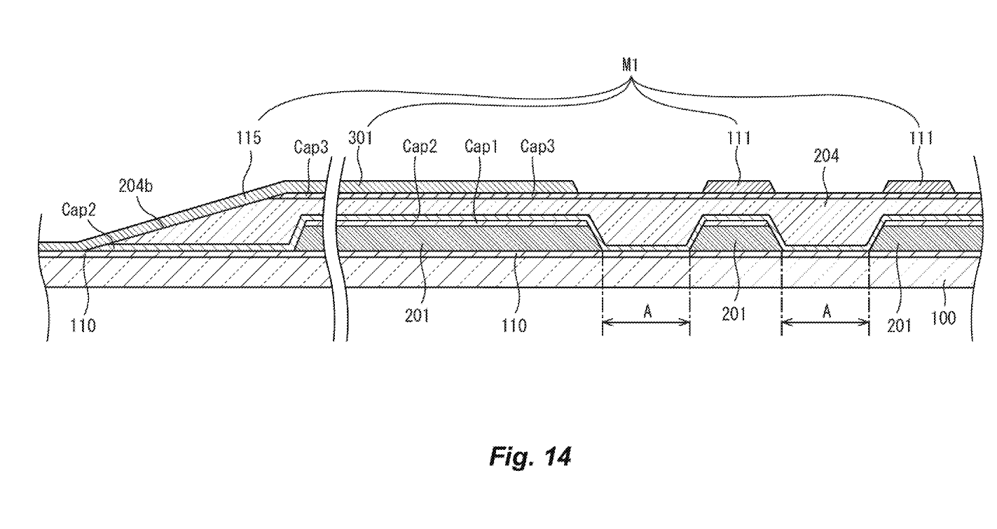

Next, FIG. 14 is referred to. A metal film for forming the first conductive films M1 is formed by sputtering on the third transparent insulating film Cap3. The metal film is, for example, a single layer film or a laminate film containing aluminum (Al), tungsten (W), molybdenum (Mo), tantalum (Ta), chromium (Cr), titanium (Ti), copper (Cu), or the like, or any of alloys of at least two of these metals. By patterning the metal film, the first conductive films M1 are formed. The thickness of the first conductive films M1 can be set to, for example, about 50 to 500 nm.

As illustrated in FIG. 14, the first conductive films M1 form the gate electrode 301, the lines 111A lead-out line 115 that is led out of the display region, getting over the light-transmitting film 204, and the like. In the step of forming the lead-out line 115, the lead-out line 115 is formed so as to intersect with the end of the light-shielding layer 200 that the surface coating film 110 is in contact with, when viewed in the direction vertical to the translucent substrate 100. In the example illustrated in FIG. 14, the lead-out line 115 is formed so as to extend from the upper surface of the light-shielding layer 200, passing over the end surface 204b of the light-transmitting film 204, up to on the surface coating film 110.

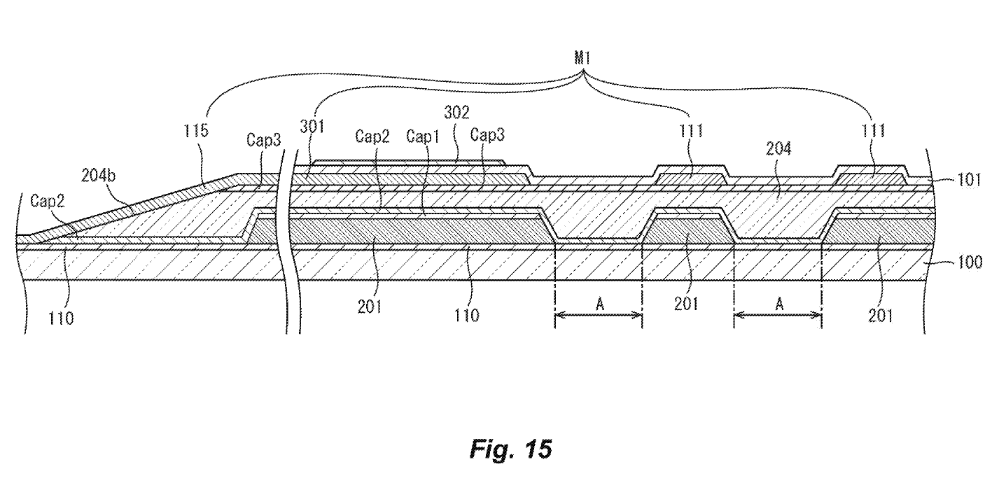

As illustrated in FIG. 15, the gate insulating film 101 is formed so as to cover the first conductive films M1 and the third transparent insulating film Cap3. The gate insulating film 101 can be formed by, for example, forming a SiNₓ film by the PECVD method. Further, the gate insulating film 101 may be a silicon-based inorganic film containing oxygen (an SiO₂ film or the like), or a laminate film composed of an SiO₂ film and a SiNₓ film. The thickness of the gate insulating film 101 can be set to, for example, 100 to 500 nm.

An oxide semiconductor film for forming the semiconductor film 302 is formed on the gate insulating film 101 by the sputtering method. By patterning the oxide semiconductor film, the semiconductor film 302 is formed in an area corresponding to the TFT 300, that is, an area opposed to the gate electrode 301.

A high temperature annealing treatment is performed to the semiconductor film 302 in a nitrogen atmosphere, in order to stabilize the transistor properties. The temperature at which the annealing treatment is carried out is, for example, 400 to 500° C. The annealing time is, for example, about one hour. The annealing, however, may be performed in, for example, a clean dry air (CDA) atmosphere, instead of a nitrogen atmosphere.

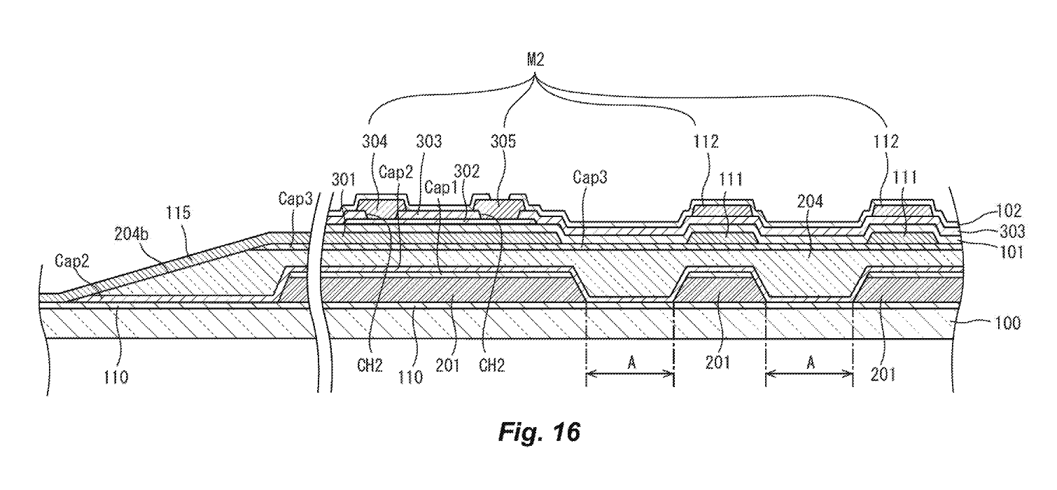

As illustrated in FIG. 16, an SiO₂ film is formed by the PECVD method so as to cover the gate insulating film 101 and the semiconductor film 302, whereby an etching stopper layer 303 is formed. The etching stopper layer 303 has a thickness of, for example, 100 to 500 nm. In the etching stopper layer 303, two contact holes CH2 are formed. As illustrated in FIG. 16, the source electrode 304 and the drain electrode 305 reach the semiconductor film 302 through these contact holes CH2.

The source electrode 304 and the drain electrode 305 are formed with the second conductive films M2 provided on the etching stopper layer 303. The second conductive film M2 can be, for example, a single layer film or a laminate film made of aluminum (Al), tungsten (W), molybdenum (Mo), tantalum (Ta), chromium (Cr), titanium (Ti), or copper (Cu), or alternatively, an alloy of at least two of these. The second conductive films M2 are formed by forming a metal film by the sputtering method and patterning the formed film by photolithography. With the second conductive films M2, for example, the source electrode 304, the drain electrode 305, the line 112, a signal line (not shown), and the like can be formed. The thickness of the second conductive film M2 can be set to, for example, 50 to 500 nm.

An SiO₂ film is formed by the PECVD method so as to cover the second conductive films M2 and the etching stopper layer 303, whereby the passivation film 102 is formed. The thickness of the passivation film 102 can be set to, for example, 100 to 500 nm.

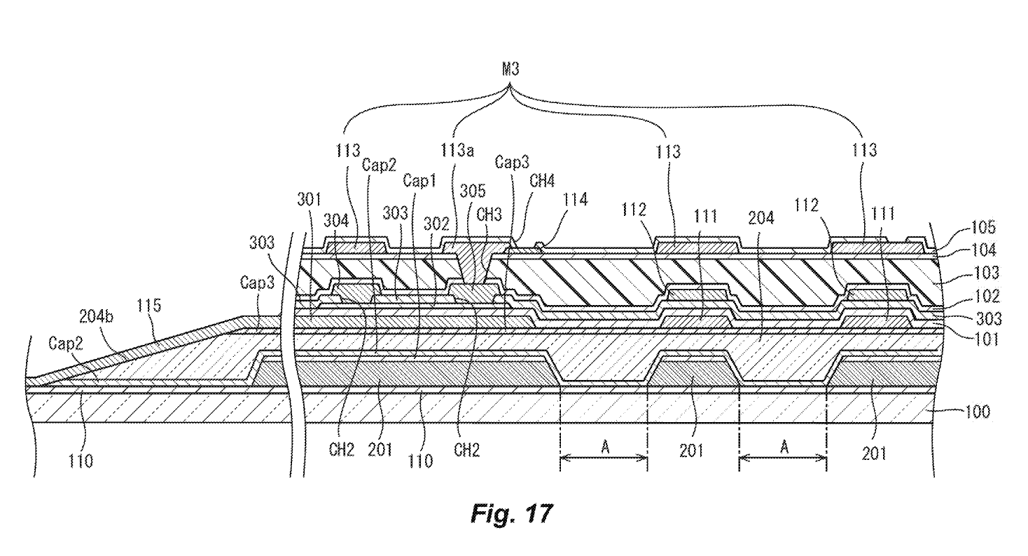

As illustrated in FIG. 17, a photosensitive resin film is formed by the spinning method so as to cover the passivation film 102, whereby the flattening film 103 is formed. The thickness of the flattening film 103 can be set to, for example, 1.0 to 3 μm.

An SiNₓ film is formed by the PECVD method so as to cover the flattening film 103, whereby the passivation film 104 is formed. The passivation film 104 has a thickness of, for example, 100 to 500 nm. The passivation film 104, the flattening film 103, and the passivation film 102 are etched, whereby a contact hole CH3 extending from the surface of the passivation film 104 and reaching the drain electrode 305 is formed.

The transparent conductive film 114 is formed by, for example, the sputtering method, on the surface of the passivation film 104, in the vicinity of the contact hole CH3.

Further, the third conductive films M3 for forming the lines 113a, 113 are formed on the passivation film 104. The third conductive film M3 can be, for example, a single layer film or a laminate film containing aluminum (Al), tungsten (W), molybdenum (Mo), tantalum (Ta), chromium (Cr), titanium (Ti), or copper (Cu), or alternatively, an alloy of at least two of these. The third conductive films M3 are formed by forming a metal film by the sputtering method and patterning the formed film by photolithography. The third conductive films M3 form the lines 113, 113a in areas that do not overlap the light-transmitting areas A.

As illustrated in FIG. 17, an SiNₓ film is formed by the PECVD method on the passivation film 104 so as to cover the lines 113, the transparent conductive film 114, and the like, whereby the passivation film 105 is formed. The passivation film 105 has a thickness of, for example, 100 to 500 nm. Then, by etching the passivation film 105, a contact hole CH4 extending from the surface of the passivation film 105 and reaching the light-transmitting film 114 is formed.

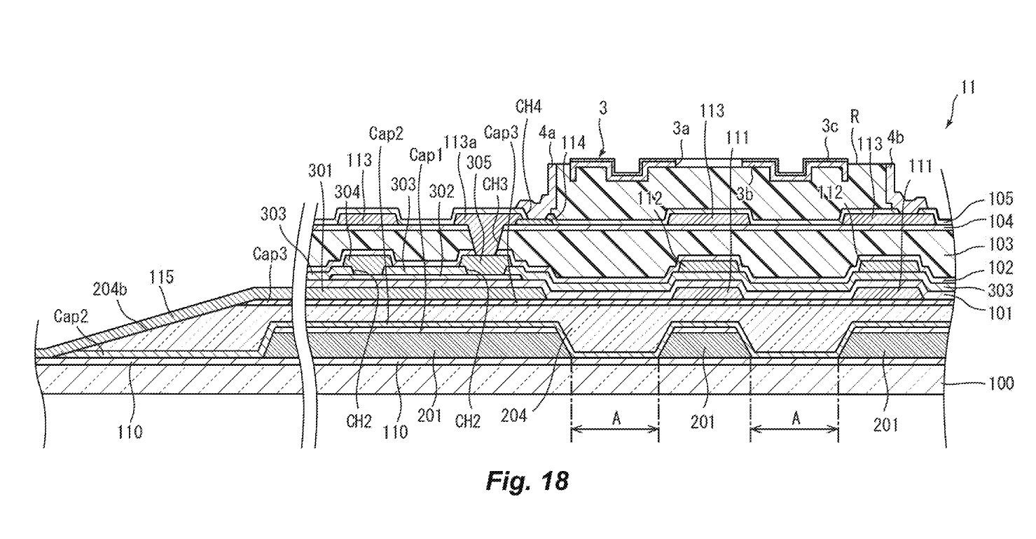

Next, as illustrated in FIG. 18, a resist R is applied to an area including at least the light-transmitting area A, by using, for example, the spin coating method.

Next, an amorphous silicon (a-Si) layer is formed by the PECVD method so as to cover the resist R. Here, a film is formed so as to cover both of the upper surface and the side surface of the resist R. The a-Si layer formed has a thickness of, for example, 200 to 500 nm. Then, the a-Si layer is patterned by photolithography, whereby the first electrode portion 4a, the second electrode portion 4b, the shutter beam 5 (not illustrated in FIG. 18), and the shutter main body 3b are formed. The first electrode portion 4a and the second electrode portion 4b are composed of portions of the a-Si layer formed on side surfaces of the resist R.

Subsequently, the metal film 3c is provided on the shutter main body 3b. With this, the shutter body 3 is formed. The metal film 3c can be formed with a metal film that contains any one of, for example, aluminum (AI), tungsten (W), molybdenum (Mo), tantalum (Ta), chromium (Cr), titanium (Ti), copper (Cu), and an alloy of at least two of these metals. The metal film 3c is formed by the sputtering method.

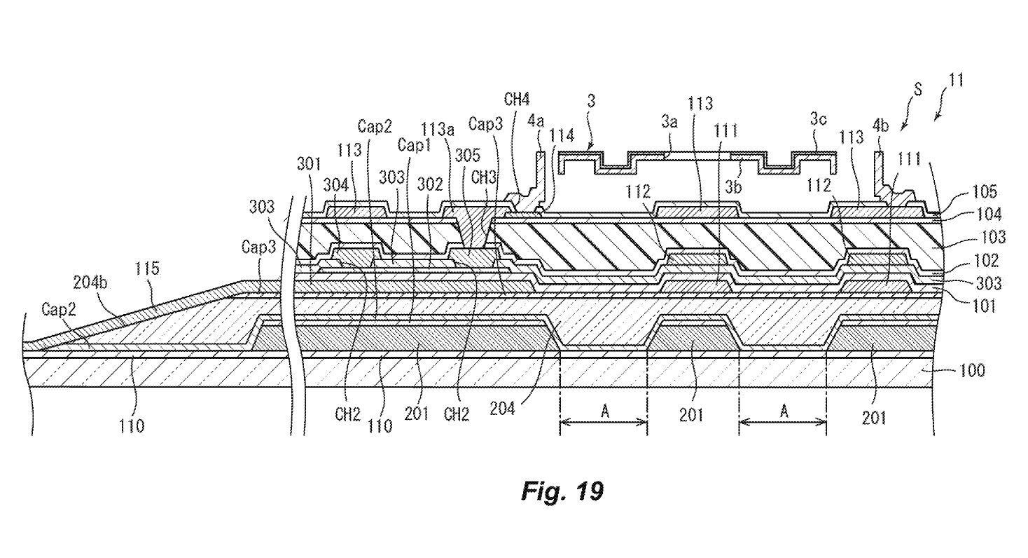

As illustrated in FIG. 19, the resist R is removed by the spinning method. This causes the shutter bodies 3 to be arranged in a state of being floated from the passivation film 105, with a space therebetween. The shutter bodies 3 are supported by the shutter beam anchors 8 (not illustrated), via the shutter beams 5 (not illustrated).

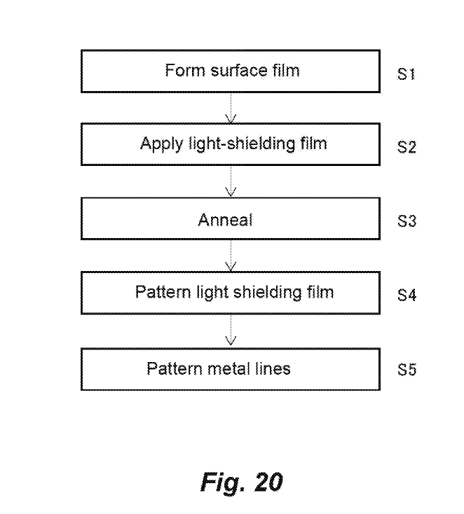

Through the above-described steps, the first substrate 11 is manufactured. FIG. 20 schematically illustrates the flow of the above-described manufacturing method. In the example illustrated in FIG. 20, the surface coating film 110 is formed on the translucent substrate 100 (S1), and a material for forming the light-shielding layer 200 is applied thereon (S2). In the present example, at S2, an application liquid for the SOG film 204S for forming the light-transmitting film 204 is applied. The application liquid thus applied is annealed (S3), and is patterned (S4).

In the patterning at S4, for example, dry etching is used. The etching rate and the thickness of the surface coating film 110 can be set so that the surface coating film 110 remains in an area from which the SOG film 204S is to be removed by this dry etching. This makes it possible to suppress the formation of a plurality of needle-like protrusions on the surfaces of the translucent substrate 100 and the light-shielding layer 200 in the vicinity of the end of the light-shielding layer 200.

In the layer above the light-shielding layer 200, a conductive film is formed, and metal lines are formed by patterning (S5). Lines that get over the end of the light-shielding layer 200 are formed. The lines formed by the above-described manufacturing method, getting over the end of the light-shielding layer 200, hardly become disconnected or have a high resistance. As a result, the occurrence of line defects decreases. Consequently, the yield increases, and the production costs are reduced.

### Modification Example

In the above-described embodiment, the light-shielding film 201 is formed so as to cover the display region 13 other than the light-transmitting area A. The light-shielding film 201 may be provided in an area where at least the TFTs 300 are formed. This makes it possible to prevent the TFTs 300 from being exposed to external light that has advanced from the viewing side of the display device 10.

In the above-described embodiment, the light-transmitting film 204 is provided so as to cover the light-shielding film 201. In contrast, the light transmitting film 204, however, may be provided in the same layer as the light-shielding film 201.

In the above-described embodiment, the surface coating film 110 is formed over the entirety of the surface of the translucent substrate 100. The surface coating film 110 can be formed in an area including at least the end of the light-shielding layer 200, in the surface of the translucent substrate 100. This makes it possible to prevent protrusions from being formed in the vicinity of the end of the light-shielding layer 200.

In the above-described embodiment, at least one of the first transparent insulating film Cap1, the second transparent insulating film Cap2, and the third transparent insulating film Cap3 can be omitted. By omitting at least one of these films, the manufacturing process can be simplified. This makes it possible to reduce the production costs.

In the present embodiment, each of the first transparent insulating film Cap1, the second transparent insulating film Cap2, and the third transparent insulating film Cap3 may be a silicon-based inorganic film containing oxygen (SiO₂ film), or may be a silicon nitride film containing nitrogen (SiNₓ film). Or alternatively, it may be a laminate film of these films. In the configuration described above, the PECVD method is used as the respective methods for forming the first transparent insulating film Cap1, the second transparent insulating film Cap2, and the third transparent insulating film Cap3, but they may be formed by the sputtering method.

### Embodiment 2

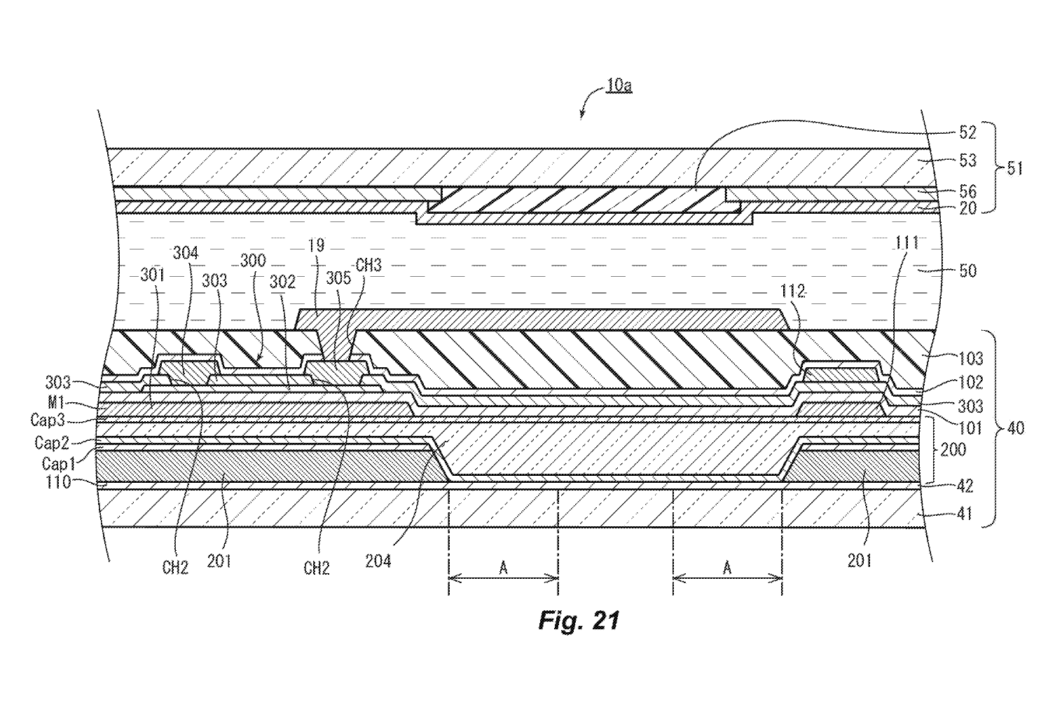

FIG. 21 is a cross-sectional view illustrating an exemplary configuration of a display device in Embodiment 2. A display device 10a illustrated in FIG. 21 is a liquid crystal display device. The display device 10a includes an active matrix substrate 40 on which TFTs 300 are arranged, a counter substrate 51 opposed to the active matrix substrate 40, and a liquid crystal layer 50 sealed between the active matrix substrate 40 and the counter substrate 51. On a side of the active matrix substrate 40 opposite to the liquid crystal layer 50, a backlight (not shown) is arranged.

The active matrix substrate 40 includes a substrate 41 (an exemplary insulating substrate). On the substrate 41, a surface coating film 42 is provided that covers the surface of the substrate 41. On the surface coating film 42, the following are laminated: a light-shielding film 201; a first transparent insulating film Cap1; a second transparent insulating film Cap2; a light-transmitting film 204; and a third transparent insulating film Cap3. These layers can be formed in a similar manner as in Embodiment 1 described above.

On the light-transmitting film 204, TFTs 300 and lines 112 are arranged, with the third transparent insulating film Cap3 being interposed therebetween. Each TFT 300 is composed of a gate electrode 301, a gate insulating film 101, a semiconductor film 302, an etching stopper layer 303, a source electrode 304, and a drain electrode 305. The TFT 300 can have a configuration similar to that in Embodiment 1.

The TFT including the source electrode 304 and the drain electrode 305 is covered with a passivation film 102. The passivation film 102 is further covered with a flattening film 103. In the passivation film 102 and the flattening film 103, a contact hole CH3 is provided that reaches the drain electrode 305. On the passivation film 104, a pixel electrode 19 is formed. A part of the pixel electrode 19 is provided so as to cover the surface of the contact hole CH3, and is electrically connected with the drain electrode 305. The pixel electrode 19 is formed with the third conductive film M3. In the active matrix substrate 40, other members may be provided, in addition to the members illustrated in FIG. 21; for example, a light distribution film and a polarization film provided so as to be in contact with the liquid crystal layer 50 may be provided.

The counter substrate 51 includes a substrate 53. On the substrate 53, color filters 52, a counter electrode (common electrode) 20, and a black matrix 56 are arranged. On the counter substrate 51, the counter electrode 20 is provided at a position opposed to the pixel electrodes 19 with the liquid crystal layer 50 being interposed therebetween. Further, the color filter layers 52 are arranged at positions corresponding to the pixels, respectively. At positions surrounding the pixels, the black matrix 56 is arranged. In other words, at positions corresponding to portions of the boundaries between adjacent ones of the pixels, the black matrix 56 is provided. More specifically, the black matrix 56 is provided in an area that is superposed on the data lines D and the gate lines G when viewed in a direction vertical to the substrate 41. Further, the black matrix 56 may be provided in an area that is superposed on the TFTs 400. On the counter substrate 51, other members may be provided, in addition to the members illustrated in FIG. 21; for example, a light distribution film and a polarization film that are provided in contact with the liquid crystal layer 50, and the like, may be provided.

On the active matrix substrate 40, the light-shielding film 201 can be provided in an area that is superposed on the black matrix 56 on the counter substrate 51, when viewed in the direction vertical to the substrate. For example, the light-shielding film 201 can be provided in an area that is superposed on the data lines D and the gate lines G. Further, the light-shielding film 201 also can be provided in an area superposed on the TFTs 300. This makes it possible to prevent light incident through the substrate 41 from being reflected on metals of lines or the TFTs 300. Consequently, the display quality is improved.

In the example illustrated in FIG. 21, the light-transmitting film 204 is formed with an application material, which makes it easy to form the light-transmitting film 204 with a greater thickness. Accordingly, in a case where, for example, the light-shielding film 201 is formed with a material having a low resistance, parasitic capacitance can be prevented from occurring between the light-shielding film 201, and conductive bodies in the TFTs 300 or the lines 111, 112 on the light-transmitting film 204. Further, by forming the light-transmitting film 204 with an application material, steps formed by the light-shielding film 201 can be reduced. This makes it easier to flatten the surface of a film covering the light-shielding film 201.

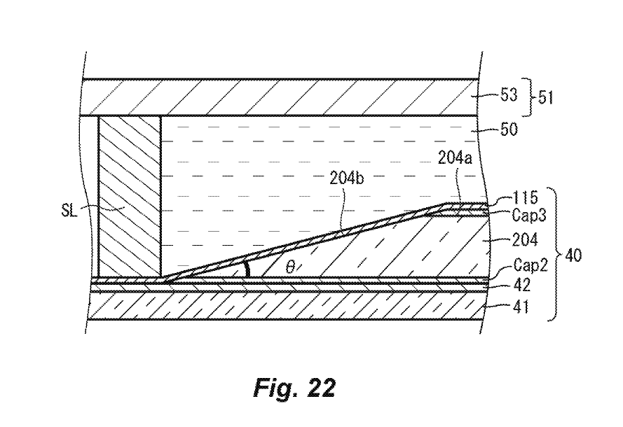

FIG. 22 is a cross-sectional view illustrating an exemplary configuration in the vicinity of an end of the light-transmitting film 204. In the example illustrated in FIG. 22, the active matrix substrate 40 and the counter substrate 51 are bonded to each other at peripheral portions of the substrates 41, 53, with a sealing member SL. The liquid crystal filled between the two substrates 41, 53 is sealed by the sealing member SL. In other words, the liquid crystal layer 50 is sealed by the sealing member SL provided between the active matrix substrate 41 and the counter substrate 51.

The end of the light-transmitting film 204 can be formed in a similar manner as the end of the light-transmitting film 204 in Embodiment 1. On the end surface 204b at the end of the light-transmitting film 204, lead-out lines 115 are formed. The lead-out lines 115 are parts of the lines connected to the TFTs 300. For example, data lines D connected to the source electrodes 46 of the TFT 300 and other lines are connected with the lead-out lines 115. In this way, at least parts of the lines connected to the TFTs 300 are led out to the outside of the sealing member SL, by the lead-out lines 115 passing over the end of the light-transmitting film 204.

In an outer peripheral portion, the light-transmitting film 204 has a thickness gradually decreasing as the proximity to the display region decreases. More specifically, the end surface 204b of the light-transmitting film 204 is inclined with respect to the surface of the substrate 41 in such a manner that the height thereof from the substrate 41 decreases as the proximity to the display region where the pixels are arranged decreases. The angle θ formed between end surface 204b of the light-transmitting film 204 and the substrate 41 is preferably smaller than 20°. Further, it is more preferably that the angle θ is set to 3° or greater, and 10° or smaller. This causes disconnection to hardly occur to lines and the like getting onto the light-transmitting film 204 from the surface of the substrate 41 (in FIG. 22, the lead-out line 115).

Further, in the present embodiment, as is the case with Embodiment 1, the surface of the substrate 41 is covered with the surface coating film 42, whereby the substrate 41 can be prevented from being exposed at the end of the light-transmitting film 204 when the light-transmitting film 204 is etched. This makes it possible to suppress the formation of protrusions.

The surface coating film 42 can be formed with a material that is etched to a lower degree in the etching performed during patterning for forming the end of the light-transmitting film 204, as compared with the material of the end of the light-transmitting film 204. This makes it easier to allow the surface coating film 42 to remain in an area in contact with the end of the light-transmitting film 204, when the light-transmitting film 204 is etched.

The light-transmitting film 204 can be formed with, for example, an application material. As the application material, the same material as the application material in Embodiment 1 can be used.

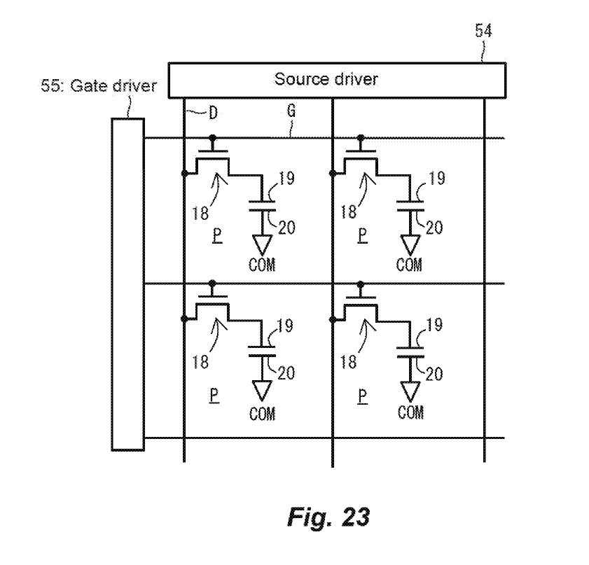

FIG. 23 illustrates an exemplary configuration of a display device 10a illustrated in FIGS. 21 and 22. In the example illustrated in FIG. 23, a plurality of gate lines (scanning lines) G, and a plurality of data lines (source lines) D arrayed so as to intersect with the gate lines G are provided in the display device 10a. The gate lines G are connected to the gate driver 55, and the data lines D are connected to the data driver 54. The gate lines G can be formed with, for example, the first conductive films M1 that are in the same layer as the gate electrode 301 illustrated in FIG. 21. The data lines D can be formed with, for example, the second conductive films M2 in the same layer as the source electrode 304 and the drain electrode 305 illustrated in FIG. 21.

At points of intersection of these data lines D and gate lines G, pixels P are provided, respectively. In each pixel P, a TFT 300, and a pixel electrode 19 connected to the TFT 300, are included. The gate lines G are connected to the gates of the TFTs 300, the data lines D are connected to the sources of the TFTs 300, and the pixel electrodes 19 are connected to the drains of the TFTs 300. In this way, in the display device 10a, a plurality of areas of each pixel P are formed in each of the areas defined in matrix by the data lines D and the gate lines G. In the display device 10a, an area where the pixels P are formed is the display region.

The display device 10a of the present invention can be applied to, for example, a see-through-type liquid crystal display that allows an object that is present on the back side of the liquid crystal display to be seen through the liquid crystal display. This is because, in the see-through-type liquid crystal display as well, it is useful to form the light-shielding layer on the display viewing side of conductive films, in order to prevent external light advancing from the display viewing side into the display device from being reflected on the conductive films such as gate lines. This light-shielding layer can be formed with the light-shielding film 201 and the light-transmitting film 204 of the above-described embodiment.

Incidentally, the above-described configuration can be such that no light-shielding film 201 is provided. In addition, the present invention can be applied to a liquid crystal display other than the see-through-type liquid crystal display.

### Embodiment 3

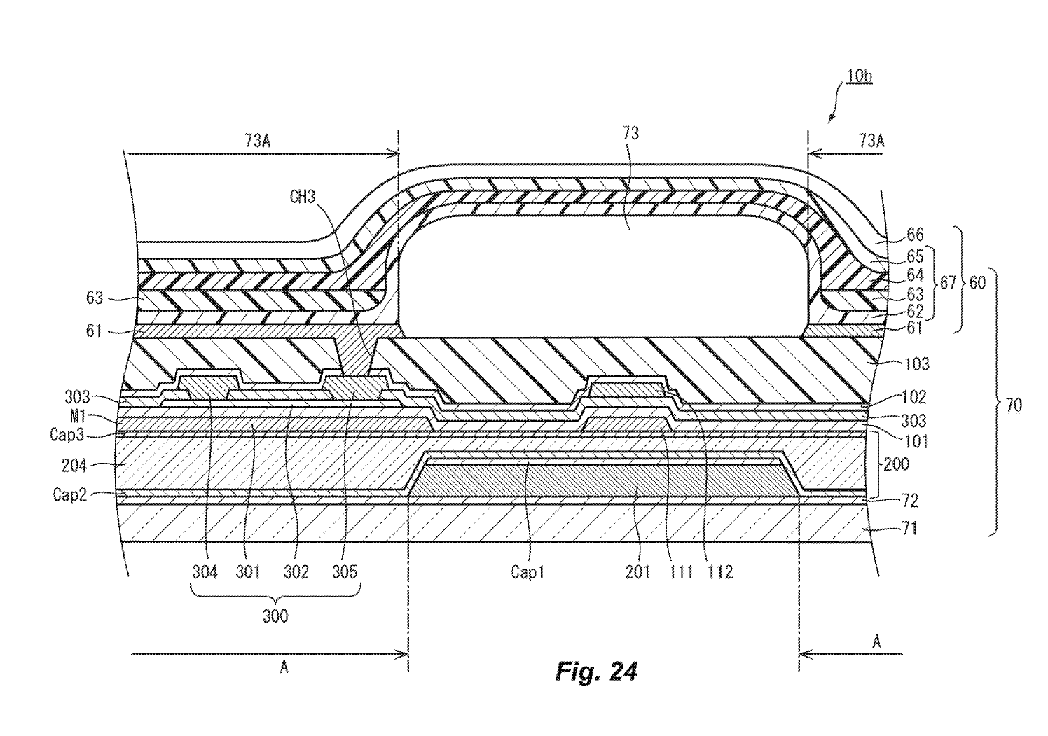

FIG. 24 is a cross-sectional view illustrating an exemplary configuration of a display device in Embodiment 3. A display device 10b illustrated in FIG. 24 is a bottom emission type organic electroluminescence display (organic EL display). The display device 10b includes an active matrix substrate 70. The active matrix substrate 70 includes a substrate 71 (an exemplary insulating substrate), TFTs 300 arranged in matrix on the substrate 71, and organic EL elements 60 connected to the TFTs 300. Further, though not illustrated, an enclosure substrate is provided so as to be opposed to the substrate 71, with an adhesive layer covering the organic EL elements 60 being interposed therebetween. With this, the organic EL elements 60 are enclosed between the substrate 71 and the enclosure substrate.

The active matrix substrate 70 has a configuration in which a surface coating film 72, a light-shielding layer 200, TFTs 300, and organic EL elements 60 are laminated on the substrate 71 in the stated order. The light-shielding layer 200 includes a light-shielding film 201, a first transparent insulating film Cap1, a second transparent insulating film Cap2, a light-transmitting film 204, and a third transparent insulating film Cap3. Each TFT 300 includes a gate electrode 301, a semiconductor film 302, an etching stopper layer 303, a source electrode 304, and a drain electrode 305. The light-shielding layer 200 and the TFTs 300 are formed in the same manner as that in Embodiment 1 or 2. Further, in a layer above the light-transmitting film 204, lines 111, 112 are provided.

Though not illustrated, a plurality of gate lines, and a plurality of data lines that intersect with the gate lines are provided in a layer above the light-transmitting film 204. The gate lines are connected to a gate line driving circuit for driving the gate lines, and the data lines are connected to a signal line driving circuit for driving the data lines. Pixels are arranged at positions corresponding to points of intersection between the gate lines and the data lines, respectively. At the pixels, the TFTs 300 connected to the gate lines and the data lines are arranged, respectively. The pixels are arranged in matrix. The pixels include pixels emitting light of red (R), pixels emitting light of blue (B), and pixels emitting light of green (G).

In the passivation film 102 and the flattening film 103, a contact hole CH3 extending to the drain electrode 305 is formed. A first electrode 61 of the organic EL element 60 is formed on the flattening film 103. A part of the first electrode 61 is provided so as to cover the surface of the contact hole CH3, and is electrically connected to the drain electrode 305. The first electrode 61 can be formed with, for example, a third conductive film M3.

An edge cover 73 is formed so as to cover an end of the first electrode 61 on the flattening film 103. The edge cover 73 is an insulating layer for preventing the first electrode 61 and the second electrode 66 from becoming short-circuited due to a decrease in the thickness of the organic EL layer 67, the occurrence of electric field concentration, or the like at the end of the first electrode 61.

In the edge cover 73, an opening 73A is provided for each pixel. The opening 73A of the edge cover 73 is a light emission area of each pixel. In other words, each pixel is separated by the edge cover 73 having insulating properties. The edge cover 73 functions as an element separation film.

The organic EL element 20 is a light emitting element that is capable of performing high-luminance light emission with low-voltage direct-current driving, and includes a first electrode 61, an organic EL layer 67, and a second electrode 66 in this order. The first electrode 61 is a layer that has a function of injecting (supplying) holes into the organic EL layer 67.

The organic EL layer 27 includes a hole injection-transport layer 62, a light emission layer 63, an electron transport layer 64, and an electron injection layer 65, in the stated order from the first electrode 61 side, between the first electrode 61 and the second electrode 66. In the present embodiment, the first electrode 61 is an anode and the second electrode 66 is a cathode, but the configuration may be such that the first electrode 61 is a cathode and the second electrode 66 is an anode.

The hole injection-transport layer 62 has both a function as a hole injection layer and a function as a hole transport layer. The hole injection-transport layer 62 is formed uniformly over an entire display region of the active matrix substrate 70, so as to cover the first electrodes 61 and the edge covers 73. In the present embodiment, the hole injection-transport layer 62 in which the hole injection layer and the hole transport layer are integrated is provided, but the present invention is not limited to this. The hole injection layer and the hole transport layer may be formed as layers independent from each other.

On the hole injection-transport layer 62, the light emission layers 63 are formed so as to cover the openings 73A in the edge cover 73, corresponding to the pixels, respectively. The light emission layer 63 is a layer that has a function of recombining a hole injected from the first electrode 61 side and an electron injected from the second electrode 66 side so as to emit light. The light emission layer 63 contains a material having a high light emission efficiency such as a low-molecular fluorescent pigment, a metal complex, or the like.

The electron transport layer 64 is a layer that has a function of enhancing the efficiency of electron transport from the second electrode 66 to the light emission layer 63B. The electron injection layer 65 is a layer that has a function of enhancing the efficiency of electron injection from the second electrode 66 to the light emission layer 63. The second electrode 66 is a layer that has a function of injecting electrons into the organic EL layer 67. The electron transport layer 64, the electron injection layer 65, and the second electrode 66 are formed uniformly over an entire surface of the display region on the active matrix substrate 70.

In the present embodiment, the electron transport layer 64 and the electron injection layer 65 are provided as layers independent from each other, but the present invention is not limited to this. A single layer in which the two are integrated (i.e., an electron transport-injection layer) may be provided. Incidentally, organic layers other than the light emission layer 63 may be omitted appropriately as required. Further, the organic EL layer 67 may further include a carrier blocking layer or another layer as required.

In the example illustrated in FIG. 24, the light-shielding film 201 is arranged at such a position that the light-shielding film 201 is superposed on the edge cover 73, when viewed in a direction vertical to the substrate 71. In other words, the light-shielding film 201 is provided in an area other than the light emission area of each pixel. For example, the light-shielding film 201 can be provided in an area that is superposed on the lines such as the data lines or the gate lines. Alternatively, the light-shielding film 201 can be provided in an area superposed on the TFTs 300. This makes it possible to prevent light incident through the substrate 71 from being reflected on metals of the TFTs 300 and lines. Consequently, the display quality is improved.

In the example illustrated in FIG. 24, as is the case with Embodiment 1 or 2, the light-transmitting film 204 can be formed with an application material.

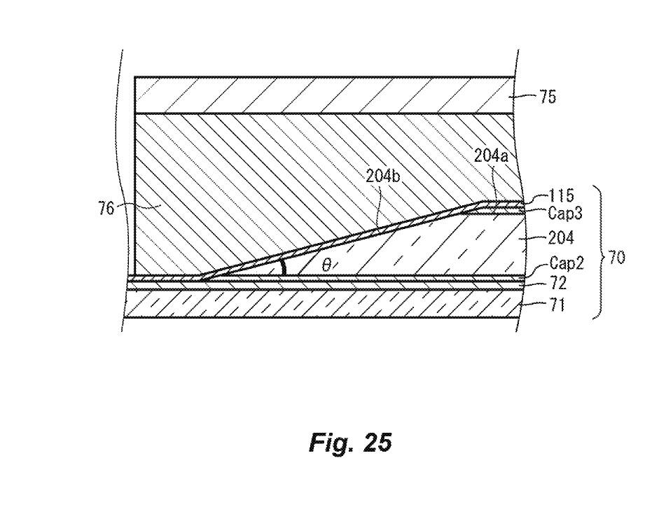

FIG. 25 is a cross-sectional view illustrating an exemplary configuration in the vicinity of an end of the light-transmitting film 204. In the example illustrated in FIG. 25, the active matrix substrate 70 and the enclosure substrate 75 are arranged so as to be opposed to each other with an adhesive layer 76 being interposed therebetween. In other words, the active matrix substrate 70 and the enclosure substrate 75 are bonded to each other with the adhesive layer 76 covering the organic EL elements 60.

The end of the light-transmitting film 204 can be formed in the same manner as that for the end of the light-transmitting film 204 in Embodiment 1 or 2. On the end surface 204b at the end of the light-transmitting film 204, the lead-out lines 115 are formed.

The end surface 204b of the light-transmitting film 204 is inclined with respect to the surface of the substrate 71 in such a manner that the height thereof from the substrate 71 decreases as the proximity thereof to the display region where the pixels are arranged decreases. The angle θ formed between end surface 204b of the light-transmitting film 204 and the substrate 71 is preferably smaller than 20°. Further, it is more preferably that the angle θ is set to 3° or greater, and 10° or smaller. This causes disconnection to hardly occur to lines and the like getting onto the light-transmitting film 204 from the surface of the substrate 71 (in FIG. 25, the lead-out line 115).

Further, in the present embodiment, as is the case with Embodiment 1 or 2, the surface of the substrate 71 is covered with the surface coating film 72, whereby the substrate 71 can be prevented from being exposed at the end of the light-transmitting film 204 when the light-transmitting film 204 is etched. This makes it possible to suppress the formation of protrusions. As the materials for the surface coating film 42 and the light-transmitting film 204, materials identical to those in Embodiment 1 or 2 can be used.

In the bottom emission type organic EL display, as in the present embodiment, it is useful to form the light-shielding layer on the display viewing side of conductive films, in order to prevent external light advancing from the display viewing side into the display device from being reflected on the conductive films such as gate electrodes. This light-shielding layer can be formed with the above-described light-shielding film 201 and light-transmitting film 204.

Incidentally, the above-described configuration can be such that no light-shielding film 201 is provided. In addition, the present invention can be applied to a top emission type organic EL display as well.

The description of Embodiments 1 to 3 explains that the semiconductor film 302 of the TFT 300 is formed with a compound (In—Ga—Zn—O) containing indium (In), gallium (Ga), zinc (Zn), and, oxygen (O), but the present invention is not limited to this. The semiconductor layer of the TFT 300 may be formed with a compound (In-Tin-Zn—O) containing indium (In), tin (Tin), zinc (Zn), and oxygen (O), a compound (In—Al—Zn—O) containing indium (In), aluminum (Al), zinc (Zn), and oxygen (O), or the like.

The above-described embodiment is merely an example for implementing the present invention. The present invention, therefore, is not limited by the above-described embodiment, and the above-described embodiment can be appropriately varied and implemented without departing from the spirit and scope of the invention.

### INDUSTRIAL APPLICABILITY

The present invention is applicable to, for example, a display device.

### DESCRIPTION OF REFERENCE NUMERALS

A: light-transmitting area
P: pixel
S: shutter portion
41: substrate
42, 72, 110: surface coating film
100: translucent substrate (exemplary insulating substrate)
200: light-shielding layer
201: light-shielding film
204: light-transmitting film
300: thin film transistor (TFT)
302: semiconductor film
Cap1: first transparent insulating film
Cap2: second transparent insulating film
Cap3: third transparent insulating film

1. A active matrix substrate comprising:
an insulating substrate;
a surface coating film that covers at least a part of a surface of the insulating substrate;
an insulating light-transmitting film provided on the insulating substrate including the surface coating film;
a gate line provided on the insulating light-transmitting film;
a gate insulating film provided on the gate line;
a data line provided on the gate insulating film so as to intersect with the gate line;
a thin film transistor provided at a position corresponding to each point of intersection between the gate line and the data line; and
a lead-out line that is electrically connected with the gate line or the data line,
wherein the surface coating film is provided between the insulating substrate and the insulating light-transmitting film,
in a peripheral portion of the insulating substrate, an area where the insulating light-transmitting film is not provided is formed,
the lead-out line is provided so as to intersect with an outer circumference end of the insulating light-transmitting film, when viewed in a direction vertical to the insulating substrate, and
in the area where the insulating light-transmitting film is not provided, the surface coating film is also provided on a part in contact with the outer circumference end of the insulating light-transmitting film.

2. The active matrix substrate according to claim 1,
wherein the insulating light-transmitting film, in a part thereof, includes a light-shielding area, and
the light-shielding area is provided at least in an area that is superposed on the gate line and the data line, when viewed in the direction vertical to the insulating substrate.

3. The active matrix substrate according to claim 2,
wherein the light-shielding area is formed with a light-shielding film provided between the surface coating film and the insulating light-transmitting film, and
the light-shielding film has a plurality of openings.

4. The active matrix substrate according to claim 1,
wherein an end surface of the insulating light-transmitting film forms an inclined surface having an angle with respect to a surface of the insulating substrate.

5. The active matrix substrate according to claim 4,
wherein the angle formed between the end surface of the insulating light-transmitting film and the surface of the insulating substrate is 3° to 10°.

6. The active matrix substrate according to claim 1,
wherein the surface coating film is made of a material that is etched to a lower degree in the etching performed during patterning of the insulating light-transmitting film, as compared with the material of the insulating light-transmitting film.

7. The active matrix substrate according to claim 1,
wherein the surface coating film is made of SiO₂.

8. The active matrix substrate according to claim 1,
wherein the insulating light-transmitting film is formed with an SOG film.

9. The active matrix substrate according to claim 1,
wherein the thin film transistor contains an oxide semiconductor.

10. A display device comprising the active matrix substrate according to claim 1.

11. The display device according to claim 10, the display device further comprising:
a light-shielding film provided between the insulating substrate and the insulating light-transmitting film, the light-shielding film having a plurality of openings;
a shutter mechanism part formed in an upper layer with respect to the thin film transistor; and
a backlight arranged so as to be opposed to the insulating substrate, with the shutter mechanism part being interposed between the backlight and the insulating substrate,
wherein the shutter mechanism part includes a shutter body that controls an amount of light from the backlight that passes through the openings provided in the light-shielding film.

12. The display device according to claim 10, further comprising:
a counter substrate opposed to the active matrix substrate; and
a liquid crystal layer provided between the active matrix substrate and the counter substrate.

13. The display device according to claim 10, further comprising:
an organic EL element connected to the thin film transistor.

14. A method for manufacturing an active matrix substrate including thin film transistors arranged in matrix, the method comprising:
forming a surface coating film that covers at least a part of a surface of an insulating substrate;
forming an insulating light-transmitting film layer on the insulating substrate including the surface coating film;
forming the thin film transistors on the insulating light-transmitting film;
forming lines on the insulating light-transmitting film, the lines being electrically connected to the thin film transistors; and
forming lead-out lines that are electrically connected to the lines and are led out to a peripheral portion of the active matrix substrate,
wherein, when forming the insulating light-transmitting film, an etching treatment is performed in patterning of the insulating light-transmitting film,
wherein, in the etching treatment, in the peripheral portion of the insulating substrate, a first area where the insulating light-transmitting film is removed, and a second area where the insulating light-transmitting film is left to remain, are formed, and
etching is performed so that, in the first area, the surface coating film is left to remain at least in vicinity of an outer circumference end of the insulating light-transmitting film, which forms the second area, and
when forming the lead-out lines, the lead-out lines are formed so as to intersect with the outer circumference end of the insulating light-transmitting film.
